(19) United States
(12) Patent Application Publication
(10) Pub. No.: US 2019/0355621 A1
(43) Pub. Date: Nov. 21, 2019

(54) Method For Increasing The Verticality Of Pillars

(71) Applicant: Micromaterials LLC, Wilmington, DE (US)

(72) Inventors: Christophe Marcadal, Santa Clara, CA (US); Swaminathan Srinivasan, Pleasanton, CA (US); Amrita B. Mullick, Santa Clara, CA (US); Susmit Singha Roy, Sunnyvale, CA (US)

(21) Appl. No.: 16/411,445

(22) Filed: May 14, 2019

Related U.S. Application Data
(60) Provisional application No. 62/672,282, filed on May 16, 2018.
(60) Provisional application No. 62/754,199, filed on Nov. 1, 2018.

(51) Int. Cl. H01L 21/768; H01L 23/522; H01L 23/532

(52) U.S. Cl. CPC H01L 21/76897; H01L 23/5226; H01L 23/53209; H01L 23/53223; H01L 23/53238; H01L 23/53252; H01L 2221/1026; H01L 23/53295; H01L 21/76808; H01L 21/76829; H01L 21/7684; H01L 21/76843; H01L 21/76879; H01L 23/53266

(57) ABSTRACT

Apparatuses and methods to provide a fully self-aligned via are described. Some embodiments of the disclosure utilize a sacrificial layer to increase the verticality of the pillars during metal recess in a fully self-aligned via. The sacrificial layer can be selectively removed to create pillars that are substantially vertical.

### CROSS-REFERENCE TO RELATED APPLICATIONS

This application claims priority to U.S. Provisional Application No. 62/672,282, filed May 16, 2018 and U.S. Provisional Application No. 62/754,199, filed Nov. 1, 2018, the entire disclosures of which are hereby incorporated by reference herein.

### TECHNICAL FIELD

Embodiments of the present disclosure pertain to the field of electronic device manufacturing, and in particular, to an integrated circuit (IC) manufacturing. More particularly, embodiments of the disclosure are directed to methods of producing pillars which have an increased verticality.

### BACKGROUND

Generally, an integrated circuit (IC) refers to a set of electronic devices, e.g., transistors formed on a small chip of semiconductor material, typically, silicon. Typically, the IC includes one or more layers of metallization having metal lines to connect the electronic devices of the IC to one another and to external connections. Typically, layers of the interlayer dielectric material are placed between the metallization layers of the IC for insulation.

As the size of the IC decreases, the spacing between the metal lines decreases. Typically, to manufacture an interconnect structure, a planar process is used that involves aligning and connecting one layer of metallization to another layer of metallization.

Typically, patterning of the metal lines in the metallization layer is performed independently from the vias above that metallization layer. Conventional via manufacturing techniques, however, cannot provide the full via self-alignment. In the conventional techniques, the vias formed to connect lines in an upper metallization layer to a lower metallization are often misaligned to the lines in the lower metallization layer. The via-line misalignment increases via resistance and leads to potential shorting to the wrong metal line. The via-line misalignment causes device failures, decreases yield and increases manufacturing cost. Additionally, via manufacturing techniques can lead to overpolishing of pillars resulting in dishing and seam opening.

### SUMMARY

Apparatuses and methods to provide a fully self-aligned via are described. In one embodiment, a method to provide a fully self-aligned via is described. A substrate is provided having a first insulating layer thereon, the first insulating layer having a top surface and a plurality of trenches formed along a first direction, the plurality of trenches having recessed first conductive lines extending along the first direction and having a first conductive surface below the top surface of the first insulating layer. A sacrificial layer is formed in the plurality of trenches on the recessed first conductive lines to form a sacrificial layer overburden on the top surface of the first insulating layer. The substrate is planarized to remove the sacrificial layer overburden and a portion of the first insulating layer to expose the top surface of the first insulating layer and form a plurality of filled trenches having sharp top corners. The sacrificial layer is removed to expose the recessed first conductive lines. A first metal film is deposited on the recessed first conductive lines, and pillars are formed from the first metal film on the recessed first conductive lines, the pillars extending orthogonal to the top surface of the first insulating layer.

One or more embodiments are directed to an electronic device. In one embodiment, a first metallization layer comprises a set of first conductive lines extending along a first direction, each of the first conductive lines separated from an adjacent first conductive line by a first insulating layer. A second insulating layer is on the first insulating layer. A second metallization layer is on portions of the second insulating layer and on a third insulating layer, the second metallization layer comprising a set of second conductive lines extending along a second direction that crosses the first direction at an angle. At least one via is between the first metallization layer and the second metallization layer, wherein the at least one via is self-aligned along the second direction to one of the first conductive lines, and wherein the at least one via is substantially vertical.

In one embodiment, a method to provide a fully self-aligned via is described. A substrate is provided having a first insulating layer thereon and a capping layer on the first insulating layer, the first insulating layer having a top surface and a plurality of trenches formed along a first direction, the plurality of trenches having recessed first conductive lines extending along the first direction and having a first conductive surface below the top surface of the first insulating layer, the first insulating layer comprising ULK. A sacrificial layer is formed in the plurality of trenches on the recessed first conductive lines to form a sacrificial layer overburden on the top surface of the first insulating layer, the sacrificial layer comprising an oxide formed by flowable CVD. The sacrificial layer is removed to expose the recessed first conductive lines. A first metal film is deposited on the recessed first conductive lines, the first metal film comprising tungsten. Pillars are formed from the first metal film on the recessed first conductive lines, the pillars extending orthogonal to the top surface of the first insulating layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1A illustrates a cross-sectional view of an electronic device structure to provide a fully self-aligned via according to one embodiment;

FIG. 1B illustrates a cross-sectional view of an electronic device structure to provide a fully self-aligned via according to one embodiment;

FIG. 1C illustrates a cross-sectional view of an electronic device structure to provide a fully self-aligned via according to one embodiment;

FIG. 1D illustrates a cross-sectional view of an electronic device structure to provide a fully self-aligned via according to one embodiment;

FIG. 2A is a view similar to FIG. 1C, after the conductive lines are recessed according to one embodiment;

FIG. 2B is a view similar to FIG. 1D, after the conductive lines are recessed according to one embodiment;

FIG. 3A is a view similar to FIG. 2A, after a liner is deposited on the recessed conductive lines according to one embodiment;

FIG. 3B is a view similar to FIG. 2B, after a liner is deposited on the recessed conductive lines according to one embodiment;

FIG. 4A is a view similar to FIG. 3A, after a sacrificial layer is deposited on the recessed conductive lines according to one embodiment;

FIG. 4B is a view similar to FIG. 3B, after a sacrificial layer is deposited on the recessed conductive lines according to one embodiment;

FIG. 5A is a view similar to FIG. 4A, after the substrate is planarized according to one embodiment;

FIG. 5B is a view similar to FIG. 4B, after the substrate is planarized according to one embodiment;

FIG. 6A is a view similar to FIG. 5A, after the sacrificial layer is removed according to one embodiment;

FIG. 6B is a view similar to FIG. 5B, after the sacrificial layer is removed according to one embodiment;

FIG. 7A is a view similar to FIG. 6B, after a conformal liner is deposited according to one embodiment;

FIG. 7B is a view similar to FIG. 7A, after a seed gapfill layer is deposited on the conformal liner according to one embodiment;

FIG. 8 is a view similar to FIG. 7B, after portions of the seed gapfill layer are removed to expose top portions of the insulating layer according to one embodiment;

FIG. 9 is a view similar to FIG. 8, after self-aligned selective growth pillars are formed according to one embodiment;

FIG. 10 is an exploded view of a self-aligned growth pillar of FIG. 9 according to one embodiment;

FIG. 11 is a view similar to FIG. 9 after an insulating layer is deposited to overfill the gaps between the pillars according to one embodiment;

FIG. 12 is a view similar to FIG. 11, after a portion of the insulating layer is removed to expose the top portions of the pillars according to one embodiment;

FIGS. 13A-13B are a view similar to FIG. 12 after the self-aligned selectively grown pillars are selectively removed to form trenches according to one embodiment;

FIG. 14 is a view similar to FIG. 13A after an insulating layer is deposited into trenches according to one embodiment;

FIG. 15 is a view after an insulating layer is deposited into trenches according to one embodiment;

FIG. 16A is a view similar to FIG. 15 after a mask layer is deposited on an insulating layer on the patterned hard mask layer according to one embodiment;

FIG. 16B is a cross-sectional view of FIG. 16A along an axis C-C′;

FIG. 17A is a view similar to FIG. 16B after the insulating layer is selectively etched according to one embodiment;

FIG. 17B is a view similar to FIG. 16A after the insulating layer is selectively etched according to one embodiment;

FIG. 18A is a view similar to FIG. 14 after a mask layer is deposited on a hard mask layer according to one embodiment;

FIG. 18B is a top view of the electronic device structure depicted in FIG. 18A;

FIG. 19A is a view similar to FIG. 18A after portions of the hard mask layer and the insulating layer are removed according to one embodiment;

FIG. 19B is a top view of the electronic device structure depicted in FIG. 19A;

FIG. 20A is a view similar to FIG. 19A after a fully self-aligned opening is formed in insulating layer according to one embodiment;

FIG. 20B is a top view of the electronic device structure depicted in FIG. 20A;

FIG. 21A is a view similar to FIG. 20A after an upper metallization layer comprising conductive lines extending along a Y axis is formed according to one embodiment;

FIG. 21B is a top view of the electronic device structure depicted in FIG. 21A;

FIG. 22A is a view similar to FIG. 14 after a mask layer is deposited on a hard mask layer according to one embodiment;

FIG. 22B is a top view of the electronic device structure depicted in FIG. 22A;

FIG. 23A is a view similar to FIG. 22A after portions of the hard mask layer and the insulating layer are removed according to one embodiment;

FIG. 23B is a top view of the electronic device structure depicted in FIG. 23A;

FIG. 24A is a view similar to FIG. 23A after forming a planarization filling layer and mask layer according to one embodiment;

FIG. 24B is a top view of the electronic device structure depicted in FIG. 24A;

FIG. 25A is a view similar to FIG. 24A after a fully self-aligned opening is formed in insulating layer according to one embodiment;

FIG. 25B is a top view of the electronic device structure depicted in FIG. 25A;

FIG. 26A is a view similar to FIG. 25A after an upper metallization layer comprising conductive lines extending along a Y axis is formed according to one embodiment; and

FIG. 26B is a top view of the electronic device structure depicted in FIG. 26A.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus for example, where a film/layer or partial film/layer has been deposited onto a substrate surface, the exposed surface of the newly deposited film/layer becomes the substrate surface.

As used in this specification and the appended claims, the terms “precursor”, “reactant”, “reactive gas” and the like are used interchangeably to refer to any gaseous species that can react with the substrate surface.

Apparatuses and methods to provide a fully self-aligned via are described. In one embodiment, a method to provide a fully self-aligned via is described. A substrate is provided having a first insulating layer thereon, the first insulating layer having a top surface and a plurality of trenches formed along a first direction, the plurality of trenches having recessed first conductive lines extending along the first direction and having a first conductive surface below the top surface of the first insulating layer. A sacrificial layer is formed in the plurality of trenches on the recessed first conductive lines to form a sacrificial layer overburden on the top surface of the first insulating layer. The substrate is planarized to remove the sacrificial layer overburden and a portion of the first insulating layer to expose the top surface of the first insulating layer and form a plurality of filled trenches having sharp top corners. The sacrificial layer is removed to expose the recessed first conductive lines. A first metal film is deposited on the recessed first conductive lines, and pillars are formed from the first metal film on the recessed first conductive lines, the pillars extending orthogonal to the top surface of the first insulating layer.

In One Embodiment, the Via is Self-Aligned Along the First Direction to One of the Second Conductive Lines.

In one embodiment, a fully self-aligned via is the via that is self-aligned along at least two directions to the conductive lines in a lower (or first) and an upper (or second) metallization layer. In one embodiment, the fully self-aligned via is defined by a hard mask in one direction and the underlying insulating layer in another direction, as described in further detail below.

Comparing to the conventional techniques, some embodiments advantageously provide fully self-aligned vias with minimized bowing of the side walls during metal recess. In some embodiments, the fully self-aligned vias provide lower via resistance and capacitance benefits over the conventional vias. Some embodiments of the self-aligned vias provide full alignment between the vias and the conductive lines of the metallization layers that is substantially error free that advantageously increase the device yield and reduce the device cost. Additionally, some embodiments of the self-aligned vias provide a high aspect ratio for the fully self-aligned via. Furthermore, some embodiments of the fully self-aligned vias advantageously provide columns and vias which are straighter and have increased verticality compared to columns and vias produced by other methods.

It should be noted that while cartoon figures and drawings often depict semiconductor structures, including vias, using rectangles with square edges (i.e., 90°), this is merely for ease of drawing. As recognized by one of ordinary skill in the art, semiconductor structures, columns and vias do not have square edges. Instead, columns and vias have rounded corners and are not linear, but are more globular in shape. The methods described herein, however, advantageously produce columns and vias that are more square and straighter/vertical with substantially linear sidewalls, tops, and bottoms.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been descried in great details to avoid unnecessarily obscuring of this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

Reference throughout the specification to “one embodiment”, “another embodiment”, or “an embodiment” means that a particular feature, structure, or characteristic described in connection with the embodiment is included in a least one embodiment of the present disclosure. Thus, the appearance of the phrases “in one embodiment” or “in an embodiment” in various places throughout the specification are not necessarily all referring to the same embodiment of the disclosure. Furthermore, the particular features, structures, or characteristics may be combined in any suitable manner in one or more embodiments.

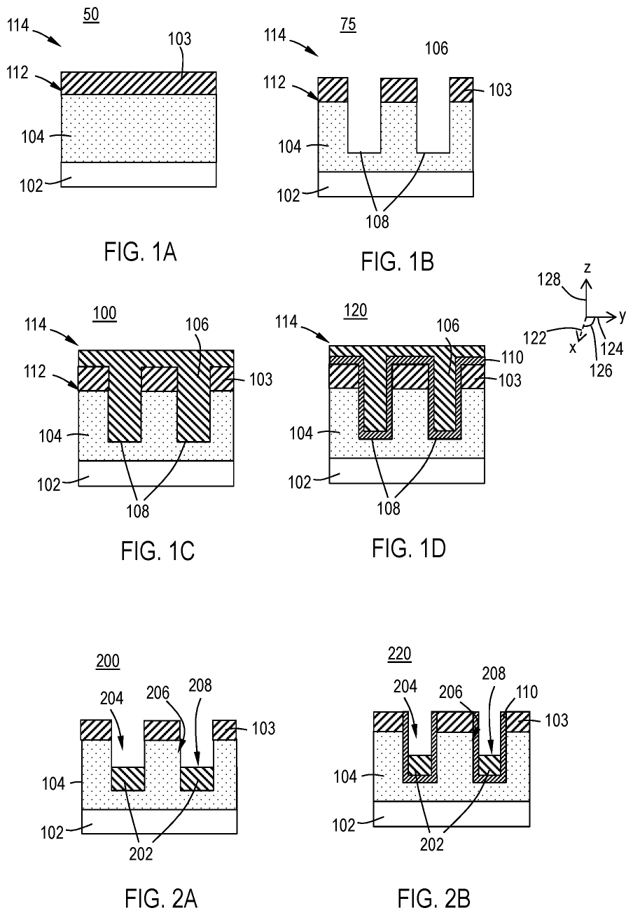

FIG. 1A illustrates a cross-sectional view 50 of an electronic device 114 structure to provide a full self-aligned via according to one embodiment. An insulating layer 104 on a substrate 102 is provided. A capping layer 103 comprising silicon nitride (SiN) is deposited on the insulating layer 104. The capping layer 103 has a thickness greater than 10 nm, including greater than 15 nm, or greater than 20 nm. FIG. 1B illustrates a cross-sectional view 75 of an electronic device 114 structure to provide a fully self-aligned via according to one embodiment. Referring to FIG. 1B, trenches 108 are formed in the insulating layer 104 and the capping layer 103.

FIG. 1C illustrates a cross-sectional view 100 of an electronic device 114 structure to provide a fully self-aligned via according to one embodiment. A lower metallization layer (Mx) comprises a set of conductive lines 106 that extend along an X axis (direction) 122 on a capping layer 103 and an insulating layer 104 on a substrate 102. The X axis of FIG. 1C extends orthogonally to the plane of the Figure page. As shown in FIG. 1C, X axis (direction) 122 crosses Y axis (direction) 124 at an angle 126. In one embodiment, angle 126 is about 90 degrees. In another embodiment, angle 126 is an angle that is other than the 90 degrees angle. The insulating layer 104 comprises trenches 108. The conductive lines 106 are deposited on the capping layer 103 and in trenches 108.

In an embodiment, the substrate 102 comprises a semiconductor material, e.g., silicon (Si), carbon (C), germanium (Ge), silicon germanium (SiGe), gallium arsenide (GaAs), indium phosphide (InP), indium gallium arsenide (InGaAs), aluminum indium arsenide (InAlAs), other semiconductor material, or any combination thereof. In an embodiment, substrate 102 is a semiconductor-on-isolator (SOI) substrate including a bulk lower substrate, a middle insulation layer, and a top monocrystalline layer. The top monocrystalline layer may comprise any material listed above, e.g., silicon. In various embodiments, the substrate 102 can be, e.g., an organic, a ceramic, a glass, or a semiconductor substrate. Although a few examples of materials from which the substrate 102 may be formed are described here, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In one embodiment, substrate 102 includes one or more metallization interconnect layers for integrated circuits. In at least some embodiments, the substrate 102 includes interconnects, for example, vias, configured to connect the metallization layers. In at least some embodiments, the substrate 102 includes electronic devices, e.g., transistors, memories, capacitors, resistors, optoelectronic devices, switches, and any other active and passive electronic devices that are separated by an electrically insulating layer, for example, an interlayer dielectric, a trench insulation layer, or any other insulating layer known to one of ordinary skill in the art of the electronic device manufacturing. In one embodiment, the substrate 102 includes one or more layers above substrate 102 to confine lattice dislocations and defects.

Insulating layer 104 can be any material suitable to insulate adjacent devices and prevent leakage. In one embodiment, electrically insulating layer 104 is an oxide layer, e.g., silicon dioxide, or any other electrically insulating layer determined by an electronic device design. In one embodiment, insulating layer 104 comprises an interlayer dielectric (ILD). In one embodiment, insulating layer 104 is a low-k dielectric that includes, but is not limited to, materials such as, e.g., silicon dioxide, silicon oxide, carbon doped oxide (“CDO”), e.g., carbon doped silicon dioxide, porous silicon dioxide (SiO₂), silicon nitride (SiN), or any combination thereof.

In one embodiment, insulating layer 104 includes a dielectric material having a K-value less than 5. In one embodiment, insulating layer 104 includes a dielectric material having a K-value less than 2. In at least some embodiments, insulating layer 104 includes oxides, carbon doped oxides, porous silicon dioxide, carbides, oxycarbides, nitrides, oxynitrides, oxycarbonitrides, polymers, phosphosilicate glass, fluorosilicate (SiOF) glass, organosilicate glass (SiOCH), or any combinations thereof, other electrically insulating layer determined by an electronic device design, or any combination thereof. In at least some embodiments, insulating layer 104 may include polyimide, epoxy, photodefinable materials, such as benzocyclobutene (BCB), and WPR-series materials, or spin-on-glass.

In one embodiment, insulating layer 104 is a low-κ interlayer dielectric to isolate one metal line from other metal lines on substrate 102. In one embodiment, the thickness of the insulating layer 104 is in an approximate range from about 10 nanometers (nm) to about 2 microns (μm).

In an embodiment, insulating layer 104 is deposited using one of deposition techniques, such as but not limited to a chemical vapor deposition (“CVD”), a physical vapor deposition (“PVD”), molecular beam epitaxy (“MBE”), metalorganic chemical vapor deposition (“MOCVD”), atomic layer deposition (“ALD”), spin-on, or other insulating deposition techniques known to one of ordinary skill in the art of microelectronic device manufacturing.

In one embodiment, the lower metallization layer Mx comprising conductive lines 106 (i.e., metal lines) is a part of a back end metallization of the electronic device. In one embodiment, the insulating layer 104 is patterned and etched using a hard mask to form trenches 108 using one or more patterning and etching techniques known to one of ordinary skill in the art of microelectronic device manufacturing. In one embodiment, the size of trenches 108 in the insulating layer 104 is determined by the size of conductive lines formed later on in a process.

In one embodiment, forming the conductive lines 106 involves filling the trenches 108 with a layer of conductive material. In one embodiment, a base layer (not shown) is first deposited on the internal sidewalls and bottom of the trenches 108, and then the conductive layer is deposited on the base layer. In one embodiment, the base layer includes a conductive seed layer (not shown) deposited on a conductive barrier layer (not shown). The seed layer can include copper (Cu), and the conductive barrier layer can include aluminum (Al), titanium (Ti), tantalum (Ta), tantalum nitride (TaN), and the like metals. The conductive barrier layer can be used to prevent diffusion of the conductive material from the seed layer, e.g., copper or cobalt, into the insulating layer 104. Additionally, the conductive barrier layer can be used to provide adhesion for the seed layer (e.g., copper).

In one embodiment, to form the base layer, the conductive barrier layer is deposited onto the sidewalls and bottom of the trenches 108, and then the seed layer is deposited on the conductive barrier layer. In another embodiment, the conductive base layer includes the seed layer that is directly deposited onto the sidewalls and bottom of the trenches 108. Each of the conductive barrier layer and seed layer may be deposited using any think film deposition technique known to one of ordinary skill in the art of semiconductor manufacturing, e.g., sputtering, blanket deposition, and the like. In one embodiment, each of the conductive barrier layer and the seed layer has the thickness in an approximate range from about 1 nm to about 100 nm. In one embodiment, the barrier layer may be a thin dielectric that has been etched to establish conductivity to the metal layer below. In one embodiment, the barrier layer may be omitted altogether and appropriate doping of the copper line may be used to make a “self-forming barrier”.

In one embodiment, the conductive layer e.g., copper or cobalt, is deposited onto the seed layer of base layer of copper, by an electroplating process. In one embodiment, the conductive layer is deposited into the trenches 108 using a damascene process known to one of ordinary skill in the art of microelectronic device manufacturing. In one embodiment, the conductive layer is deposited onto the seed layer in the trenches 108 using a selective deposition technique, such as but not limited to electroplating, electrolysis, CVD, PVD, MBE, MOCVD, ALD, spin-on, or other deposition techniques know to one of ordinary skill in the art of microelectronic device manufacturing.

In one embodiment, the choice of a material for conductive layer for the conductive lines 106 determines the choice of a material for the seed layer. For example, if the material for the conductive lines 106 includes copper, the material for the seed layer also includes copper. In one embodiment, the conductive lines 106 include a metal, for example, copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), vanadium (V), molybdenum (Mo), palladium (Pd), gold (Au), silver (Ag), platinum (Pt), indium (In), tin (Sn), lead (Pd), antimony (Sb), bismuth (Bi), zinc (Zn), cadmium (Cd), or any combination thereof.

In one embodiment, portions of the conductive layer and the base layer are removed to even out top portions of the conductive lines 106 with top portions of the insulating layer 104 using a chemical-mechanical polishing (“CMP”) technique known to one of ordinary skill in the art of microelectronic device manufacturing.

In one non-limiting example, the thickness (as measured along the z-axis of FIG. 1C) of the conductive lines 106 is in an approximate range from about 15 nm to about 1000 nm. In one non-limiting example, the thickness of the conductive lines 106 is from about 20 nm to about 200 nm. In one non-limiting example, the width (as measured along the y-axis of FIG. 1C) of the conductive lines 106 is in an approximate range from about 5 nm to about 500 nm. In one non-limiting example, the spacing (pitch) between the conductive lines 106 is from about 2 nm to about 500 nm. In more specific non-limiting example, the spacing (pitch) between the conductive lines 106 is from about 5 nm to about 50 nm.

In an embodiment, the lower metallization layer Mx is configured to connect to other metallization layers (not shown). In an embodiment, the metallization layer Mx is configured to provide electrical contact to electronic devices, e.g., transistor, memories, capacitors, resistors, optoelectronic devices, switches, and any other active and passive electronic devices that are separated by an electrically insulating layer, for example, an interlayer dielectric, a trench insulation layer, or any other insulating layer known to one of ordinary skill in the art of electronic device manufacturing.

FIG. 1D is a view 120 similar to cross-sectional view 100 of FIG. 1C, after a conformal first liner 110 is deposited on a top surface 111 of the capping layer 103 and on a top surface 112 of the insulating layer 104. The conformal first liner 110 is deposited prior to the forming the conductive lines 106. In other words, the conformal first liner 110 is deposited prior to filling the trenches 108 with a layer of conductive material.

In one or more embodiments, the conformal first liner 110 comprises one or more of titanium nitride (TiN), titanium (Ti), tantalum (Ta), or tantalum nitride (TaN). In an embodiment, the conformal first liner 110 is deposited using an atomic layer deposition (ALD) technique. In one embodiment, the conformal first liner 110 is deposited using one of deposition techniques, such as but not limited to a CVD, PVD, MBE, MOCVD, spin-on, or other liner deposition techniques know to one of ordinary skill in the art of microelectronic device manufacturing. In one embodiment, the conformal first liner 110 may be selectively removed using one or more of the dry and wet etching techniques known to one of ordinary skill in the art of electronic device manufacturing.

FIG. 2A is a view 200 similar to cross-sectional view 100 of FIG. 1C, after the conductive lines 106 are recessed according to one embodiment. The conductive lines 106 are recessed to a predetermined depth to form recessed conductive lines 202. As shown in FIG. 2A, trenches 204 are formed in the insulating layer 104. Each trench 204 has sidewalls 206 that are portions of capping layer 103, insulating layer 104, and a bottom that is a top surface 208 of the recessed conductive lines 202.

In one embodiment, the depth of the trenches 204 is from about 10 nm to about 500 nm. In one embodiment, the depth of the trenches 204 is from about 10% to about 100% of the thickness of the conductive lines. In one embodiment, the conductive lines 106 are recessed using one or more of wet etching, dry etching, or a combination thereof techniques known to one of ordinary skill in the art of electronic device manufacturing.

FIG. 2B is a view 220 similar to cross-sectional view 200 of FIG. 1D, after a conformal first liner 110 has been deposited on a top surface 112 of the insulating layer 104, as illustrated and described above with respect to FIG. 1D.

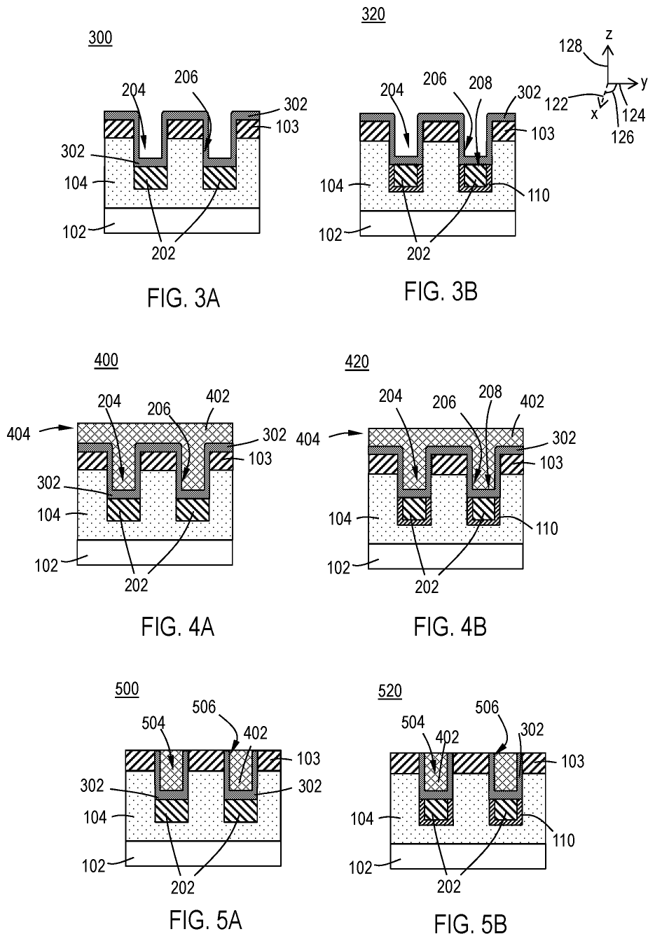

FIG. 3A is a view 300 similar to FIG. 2A, after a second conformal liner 302 is deposited on the recessed conductive lines 202 according to one embodiment. In some embodiments, the second conformal liner 302 is deposited on the sidewalls 206 of the trenches 204.

In one embodiment, second conformal liner 302 is deposited to protect the recessed conductive lines 202 from changing properties later on in a process (e.g., during tungsten deposition, or other processes). In one embodiment, second conformal liner 302 is a conductive liner. In another embodiment, second conformal liner 302 is a non-conductive liner. In one embodiment, when second conformal liner 302 is a non-conductive liner, the second conformal liner 302 is removed later on in a process, as described in further detail below. In one embodiment, second conformal liner 302 includes titanium nitride (TiN), titanium (Ti), tantalum (Ta), tantalum nitride (TaN), or any combination thereof. In another embodiment, second conformal liner 302 is an oxide, e.g., aluminum oxide (Al₂O₃), titanium oxide (TiO₂). In yet another embodiment, second conformal liner 302 is a nitride, e.g., silicon nitride (SiN) or silicon carbonitride (SiCN). In an embodiment, the second conformal liner 302 is deposited to a thickness from about 0.5 nm to about 10 nm.

In an embodiment, the second conformal liner 302 is deposited using an atomic layer deposition (ALD) technique. In one embodiment, the second conformal liner 302 is deposited using one of deposition techniques, such as but not limited to a CVD, PVD, MBE, MOCVD, spin-on, or other liner deposition techniques know to one of ordinary skill in the art of microelectronic device manufacturing.

FIG. 3B is a view 320 similar to cross-sectional view 300 of FIG. 3A, after a conformal first liner 110 has been deposited on a top surface 112 of the insulating layer 104, as illustrated and described with respect to FIG. 1D.

FIG. 4A is a view 400 similar to FIG. 3A, after a sacrificial layer 402 is deposited on the second conformal liner 302 according to one embodiment. In one embodiment, sacrificial layer 402 comprises an oxide formed by flowable CVD. In one embodiment the oxide formed by flowable CVD is any oxide known to one of skill in the art. In an embodiment, the oxide formed by flowable CVD is selected from one or more of flowable silicon oxide carbide (FSiOC), flowable silicon oxide (FSiOx), or the like. In one embodiment, the sacrificial layer has the thickness in an approximate range from about 1 nm to about 1000 nm.

As shown in FIG. 4A, sacrificial layer 402 is deposited on second conformal liner 302 on the top surface 208 of the recessed conductive lines 202, the sidewalls 206 of the trenches 204 and top portions of the insulating layer 104.

In one embodiment, the sacrificial layer 402 is deposited using one of deposition techniques, such as but not limited to an ALD, a CVD, PVD, MBE, MOCVD, spin-on or other liner deposition techniques known to one of ordinary skill in the art of microelectronic device manufacturing.

FIG. 4B is a view 420 similar to cross-sectional view 400 of FIG. 4A, after a conformal first liner 110 has been deposited on a top surface 112 of the insulating layer 104, as illustrated and described with respect to FIG. 1D.

FIG. 5A is a view 500 similar to FIG. 4A, after portions (the sacrificial layer overburden 404) of the sacrificial layer 402, the second conformal liner 302, and portions of the capping layer 103 are removed to expose the top surface of the capping layer 103 according to one embodiment. In one embodiment, the portions (the sacrificial layer overburden 404) of the sacrificial layer 402, the second conformal liner 302, and portions of the capping layer 103 are removed using one of the chemical-mechanical planarization (CMP) techniques known to one of ordinary skill in the art of microelectronic device manufacturing. During CMP, capping layer 103 is likely to decrease in thickness. The decrease in thickness may be in the range of about 2 nm to about 2 nm.

It is noted, as shown in FIG. 5A, when the substrate 102 is planarized to remove portions (the sacrificial layer overburden 404) of the sacrificial layer 402, portions of the second conformal liner 302, and portions of the capping layer 103, a plurality of filled trenches 504 are formed. The plurality of filled trenches 504 have sharp corners 506. As used herein, the phrase “sharp corners” refers to the intersection of an imaginary plane defined by the top portion (e.g., the top quarter) of the capping layer 103 (or second conformal liner 302) and an imaginary plane defined by the top surface of the sacrificial layer 402. In one or more embodiments, the intersection of the two planes forms an angle, the angle being an average of about 90° C.

FIG. 5B is a view 520 similar to cross-sectional view 500 of FIG. 5A, after a conformal first liner 110 has been deposited on a top surface 112 of the insulating layer 104, as illustrated and described with respect to FIG. 1D.

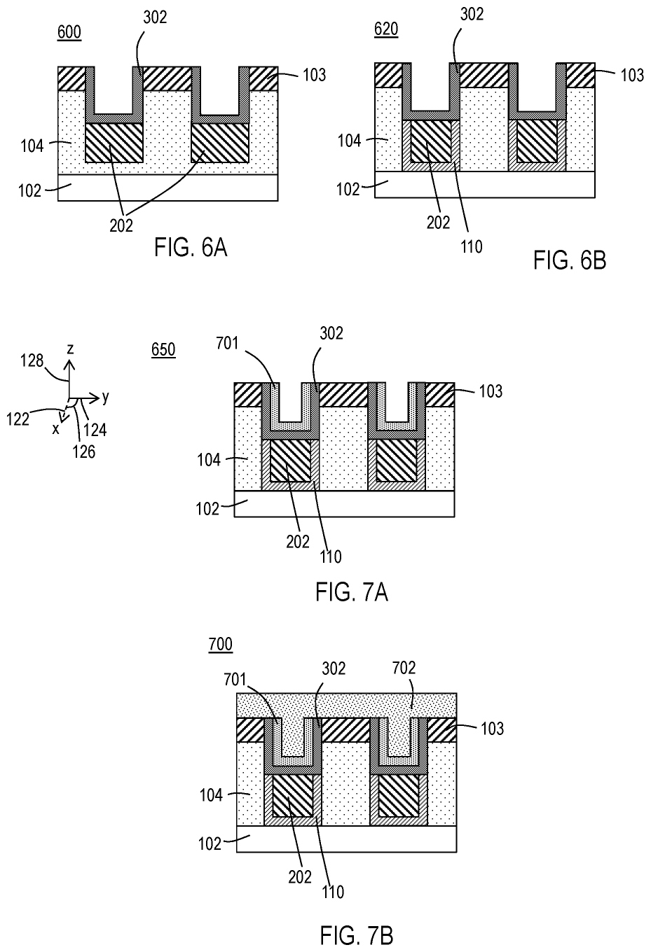

FIG. 6A is a view 600 similar to FIG. 5A, after sacrificial layer 402 is removed, exposing a top surface of capping layer 103. In some embodiments, the sacrificial layer 402 is removed by an etch process selective for the sacrificial layer 402 material relative to the second conformal liner 302, capping layer 103, recessed conductive lines 202, and insulating layer 104, such that the second conformal liner 302 remains on the top surface 208 of recessed conductive lines 202.

FIG. 6B is a view 620 similar to cross-sectional view 600 of FIG. 6A, after a conformal first liner 110 has been deposited on a top surface 112 of the insulating layer 104, as illustrated and described with respect to FIG. 1D.

While a conformal first liner 110 does not have to be present, in one or more of the foregoing embodiments, for ease of drawing, the liner has been included in the figures. FIG. 7A is a view 650 similar to FIG. 6B, after an optional third conformal liner 701 has been deposited on second conformal liner 302. Third conformal liner 701 may be deposited by any deposition technique known to one of skill in the art. In one or more embodiments, third conformal liner 701 is deposited and present. In other embodiments, third conformal liner 701 is not deposited.

FIG. 7B is a view 700 similar to FIG. 7A, after a gapfill layer 702 is deposited on the recessed conductive lines 202 (or on the second conformal liner 302, if present, or on the third conformal liner 701, if present), the capping layer 103, and a portion of the insulating layer 104 according to one embodiment. As shown in FIG. 7B, gapfill layer 702 is deposited on second conformal liner 302 (or on third conformal liner 701, if present) on the top surface 208 of the recessed conductive lines 202, the sidewalls 206 of the trenches 204, capping layer 103, and top portions of the insulating layer 104. In one embodiment, gapfill layer 702 is a tungsten (W) layer, or other gapfill layer to provide selective growth pillars. In some embodiments, gapfill layer 702 is a metal film or a metal containing film. Suitable metal films include, but are not limited to, films including one or more of cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (Al), tin (Sn), chromium (Cr), lanthanum (La), or any combination thereof. In some embodiments, seed gapfill layer 702 comprises is a tungsten (W) seed gapfill layer.

In one embodiment, the gapfill layer 702 is deposited using one of deposition techniques, such as but not limited to an ALD, a CVD, PVD, MBE, MOCVD, spin-on or other liner deposition techniques known to one of ordinary skill in the art of microelectronic device manufacturing.

In some embodiments, deposition of the gapfill layer 702 includes formation of a seed gapfill layer (not shown). As will be understood by the skilled artisan, a seed gapfill layer is a relatively thin layer of material that can increase the nucleation rate (i.e., growth rate) of the gapfill layer 702. In some embodiments, the seed gapfill layer is the same material as the gapfill layer 702 deposited by a different technique. In some embodiments, the seed gapfill layer is a different material than the gapfill layer 702.

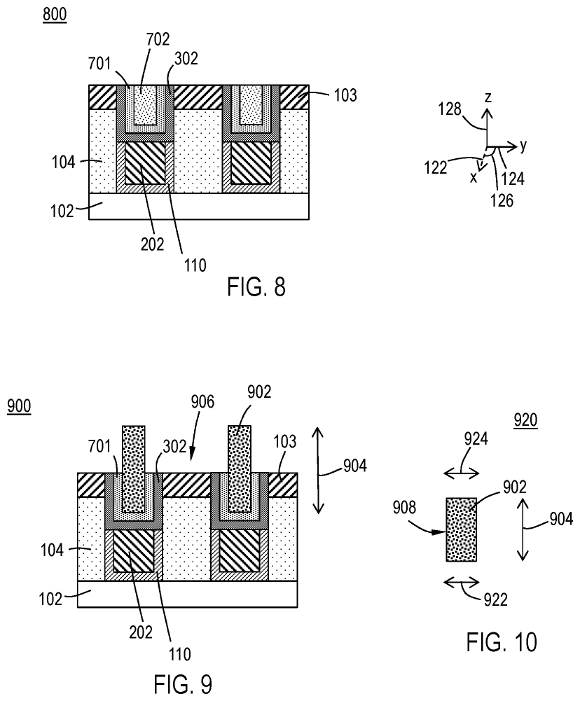

FIG. 8 is a view 800 similar to FIG. 7B, after portions of the seed gapfill layer 702 are removed to expose top portions of the insulating layer 104 according to one embodiment. In one embodiment, the portions of the seed gapfill layer 702 are removed using one of the chemical-mechanical planarization (CMP) techniques known to one of ordinary skill in the art of microelectronic device manufacturing.

The formation of the gapfill layer 702 is described in FIGS. 7B and 8 as using a bulk deposition of the gapfill material to form an overburden on the top of the substrate followed by planarization to remove the overburden. In some embodiments, the gapfill layer 702 is formed by a selective deposition process that forms substantially no (e.g., <5% area) overburden on the insulating layer 104.

FIG. 9 is a view 900 similar to FIG. 8, after self-aligned selective growth pillars 902 are formed using the seed gapfill layer 702 according to one embodiment. As shown in FIG. 9, an array of the self-aligned selective growth pillars 902 has the same pattern as the set of the recessed conductive lines 202. As shown in FIG. 9, the pillars 902 extend substantially orthogonally from the top surfaces of the recessed conductive lines 202. As shown in FIG. 9, the pillars 902 extend along the same direction as the recessed conductive lines 202. As shown in FIG. 9, the pillars are separated by gaps 906.

As shown in FIG. 10, which is exploded view 920, the pillars 902 have a height 904 and are substantially vertical with substantially linear sidewalls 908. As used herein, the term “substantially vertical” refers to pillars having substantially linear sidewalls and a pillar width that varies only about 15% or less, including about 14%, about 13%, about 12%, about 11%, about 10%, about 9%, about 8%, about 7%, about 6%, about 5%, about 4%, about 3%, about 2%, and about 1% or less, between the bottom pillar width 922 and the top pillar width 924. As used herein, the term “substantially linear” means that a major plane formed by the sidewalls 908 of the pillars 902 meet the surface of the insulating layer 104 with a relative angle in the range of about 80° to about 100°, or in the range of about 85° to about 95°, or about 90°. While the terms “vertical”, “verticality”, and the like, are used to describe the shape of the sidewalls of the pillars, these terms are referring to the surface of the insulating layer 104 as the horizon.

Referring to FIGS. 9 and 10, in one embodiment, the pillars 902 are selectively grown from the gapfill layer 702 on portions of the capping layer 103 and on the recessed conductive lines 202, when the second conformal liner 302 and the third conformal liner 701 are not present. In one embodiment, portions of the gapfill layer 702 above the recessed conductive lines 202 are expanded for example, by oxidation, nitridation, or other process to grow pillars 902. In one embodiment, the gapfill layer 702 is oxidized by exposure to an oxidizing agent or oxidizing conditions to transform the metal or metal containing gapfill layer 702 to metal oxide pillars 902. In one embodiment, pillars 902 include an oxide of one or more metals listed above. In more specific embodiment, pillars 902 include tungsten oxide (e.g., WO, WO₃ and other tungsten oxide).

The oxidizing agent can be any suitable oxidizing agent including, but not limited to, O₂, O₃, N₂O, H₂O, H₂O₂, CO, CO₂, N₂/Ar, N₂/He, N₂/Ar/He, ammonium persulphate, organic peroxide agents, such as meta-chloroperbenzoic acid and peracids (e.g. trifluoroperacetic acid, 2,4-dinitroperbenzoic acid, peracetic acid, persulfuric acid, percarbonic acid, perboric acid, and the like), or any combination thereof. In some embodiments, the oxidizing conditions comprise a thermal oxidation, plasma enhanced oxidation, remote plasma oxidation, microwave and radio-frequency oxidation (e.g., inductively coupled plasma (ICP), capacitively coupled plasma (CCP)).

In one embodiment, the pillars 902 are formed by oxidation of the seed gapfill layer at any suitable temperature depending on, for example, the composition of the seed gapfill layer and the oxidizing agent. In some embodiments, the oxidation occurs at a temperature in an approximate range of about 25° C. to about 800° C. In some embodiments, the oxidation occurs at a temperature greater than or equal to about 150° C.

In one embodiment, the height 904 of the pillars 902 is in an approximate range from about 5 angstroms (Å) to about 10 microns (μm).

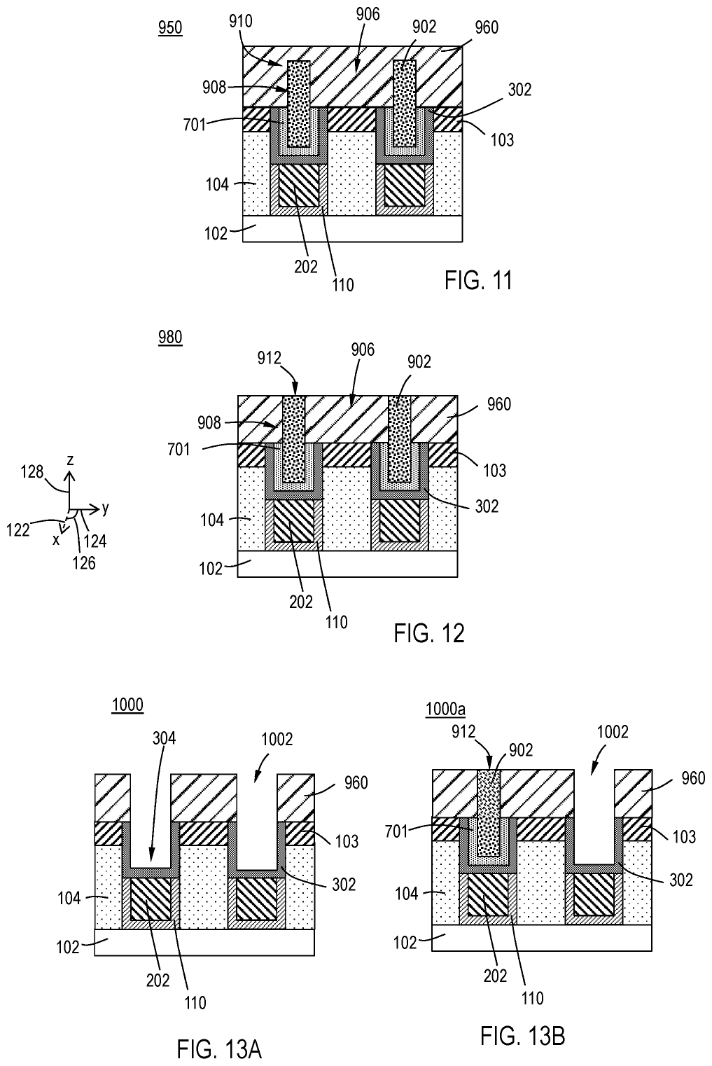

FIG. 11 is a view 950 similar to FIG. 9, and, after an insulating layer 960 is deposited to overfill the gaps 906 between the pillars 902 according to one embodiment. As shown in FIG. 11, insulating layer 960 is deposited on the opposing sidewalls 908 and top portions 910 of the pillars 902 and through the gaps 906 on the portions of the capping layer 103 and second conformal liner 302 and third conformal liner 701 between the pillars 902.

In one embodiment, insulating layer 960 is a low-κ gapfill layer. In one embodiment, insulating layer 960 is a flowable silicon oxide (FSiOx) layer. In at least some embodiments, insulating layer 960 is an oxide layer, e.g., silicon dioxide (SiO₂), or any other electrically insulating layer determined by an electronic device design. In one embodiment, insulating layer 960 is an interlayer dielectric (ILD). In one embodiment, insulating layer 960 is a low-k dielectric that includes, but is not limited to, materials such as, e.g., silicon dioxide, silicon oxide, a carbon based material, e.g., a porous carbon film, carbon doped oxide (“CDO”), e.g. carbon doped silicon dioxide, porous silicon dioxide, porous silicon oxide carbide hydride (SiOCH), silicon nitride, or any combination thereof. In one embodiment, insulating layer 960 is a dielectric material having κ-value less than 3. In more specific embodiment, insulating layer 960 is a dielectric material having κ-value in an approximate range from about 2.2 to about 2.7. In one embodiment, insulating layer 960 includes a dielectric material having κ-value less than 2. In one embodiment, insulating layer 960 represents one of the insulating layers described above with respect to insulating layer 104.

In one embodiment, insulating layer 960 is a low-κ interlayer dielectric to isolate one metal line from other metal lines. In one embodiment, insulating layer 960 is deposited using one of deposition techniques, such as but not limited to a CVD, spin-on, an ALD, PVD. MBE, MOCVD, or other low-κ insulating layer deposition techniques known to one of ordinary skill in the art of microelectronic device manufacturing.

FIG. 12 is a view 980 similar to FIG. 11, after a portion (i.e. overburden) of the insulating layer 960 is removed to expose the top surface 912 of the pillars 902 according to one embodiment. In one embodiment, the portion (i.e. overburden) of the insulating layer 960 is removed using a CMP technique known to one of ordinary skill in the art of microelectronic device manufacturing. In one embodiment, the portion (i.e. overburden) of the insulating layer 960 is etched back to expose the top surface 912 of the pillars 902 using one or more of the dry and wet etching techniques known to one of ordinary skill in the art of microelectronic device manufacturing.

In one embodiment, insulating layer 960 is deposited using one of deposition techniques, such as but not limited to a CVD, spin-on, an ALD, PVD, MBE, MOCVD, or other low-k insulating layer deposition techniques known to one of ordinary skill in the art of microelectronic device manufacturing. In another embodiment, insulating layer 960 is deposited to overfill the gaps 906 between the pillars 902, as described with respect to FIG. 11, and then a portion of the insulating layer 960 is etched back to expose upper portions of the sidewalls 908 and top surface 912 of the pillars 902 using one or more of the dry and wet etching techniques known to one of ordinary skill in the art of microelectronic device manufacturing.

FIG. 13A is a view 1000 similar to FIG. 12 after the self-aligned selectively grown pillars 902 are selectively removed to form trenches 1002 according to one embodiment. As shown in FIG. 13A, the pillars 902 are removed selectively to the insulating layer 960, the capping layer 103, and second conformal liner 302 (if present). In another embodiment, when second conformal liner 302 is a non-conductive liner, the second conformal liner 302 is removed. In one embodiment, the pillars 902, the third conformal liner 701, and second conformal liner 302 are removed selectively to the insulating layers 960 and 104, capping layer 103, and recessed conductive lines 202. As shown in FIG. 13A, trenches 1002 are formed in the insulating layers 960 and 104 and capping layer 103. Trenches 1002 extend along the same axis as the recessed conductive lines 202. As shown in FIG. 13A, each trench 1002 has a bottom that is a top surface 304 of second conformal liner 302. If there is no second conformal liner 302, the bottom of the trench 1002 would be the top surface of the recessed conductive lines 202. In another embodiment, third conformal liner 701 and second conformal liner 302 are removed so that each trench 1002 has a bottom that is a top surface of the recessed conductive lines 202 and opposing sidewalls that include portions of insulating layers 960 and 104 and capping layer 103. Generally, the aspect ratio of the trench refers to the ratio of the depth of the trench to the width of the trench. In one embodiment, the aspect ratio of each trench 1002 is in an approximate range from about 1:1 to about 200:1.

In one embodiment, the pillars 902 are selectively removed using one or more of the dry and wet etching techniques known to one of ordinary skill in the art of electronic device manufacturing. In one embodiment, the pillars 902 are selectively wet etched by e.g., 5 wt. % of ammonium hydroxide (NH₄OH) aqueous solution at the temperature of about 80° C. In one embodiment, hydrogen peroxide (H₂O₂) is added to the 5 wt. % NH₄OH aqueous solution to increase the etching rate of the pillars 902. In one embodiment, the pillars 902 are selectively wet etched using hydrofluoric acid (HF) and nitric acid (HNO₃) in a ratio of 1:1. In one embodiment, the pillars 902 are selectively wet etched using HF and HNO₃ in a ratio of 3:7 respectively. In one embodiment, the pillars 902 are selectively wet etched using HF and HNO₃ in a ratio of 4:1, respectively. In one embodiment, the pillars 902 are selectively wet etched using HF and HNO₃ in a ratio of 30%:70%, respectively. In one embodiment, the pillars 902 including tungsten (W), titanium (Ti), or both titanium and tungsten are selectively wet etched using NH₄OH and H₂O₂ in a ratio of 1:2, respectively. In one embodiment, the pillars 902 are selectively wet etched using 305 grams of potassium ferricyanide (K₃Fe(CN)₆), 44.5 grams of sodium hydroxide (NaOH) and 1000 ml of water (H₂O). In one embodiment, the pillars 902 are selectively wet etched using diluted or concentrated one or more of the chemistries including hydrochloric acid (HCl), nitric acid (HNO₃), sulfuric acid (H₂SO₄), hydrogen fluoride (HF), and hydrogen peroxide (H₂O₂). In one or more embodiments, the pillars 90 are selectively etched using a solution of HF and HNO₃, a solution of NH₄OH and H₂O₂, WCl₅, WF₆, niobium fluoride (NbF₅), chlorine with a hydrocarbon. In one or more embodiment, the hydrocarbon can be a monocarbon (e.g. CH₄) or a multicarbon-based hydrocarbon. In one embodiment, the pillars 902 are selectively wet etched using HF, HNO₃, and acetic acid (CH₃COOH) in a ratio of 4:4:3, respectively. In one embodiment, the pillars 902 are selectively dry etched using a bromotrifluoromethane (CBrF₃) reactive ion etching (RIE) technique. In one embodiment, the pillars 902 are selectively dry etched using chlorine-, fluorine-, bromine-, or any combination thereof, based chemistries. In one embodiment, the pillars 902 are selectively wet etched using hot or warm Aqua Regia mixture including HCl and HNO₃ in a ratio of 3:1, respectively. In one embodiment, the pillars 902 are selectively etched using alkali with oxidizers (potassium nitrate (KNO₃) and lead dioxide (PbO₂)). In one embodiment, the third conformal liner 701 and/or the second conformal liner 302 may be selectively removed using one or more of the dry and wet etching techniques known to one of ordinary skill in the art of electronic device manufacturing.

FIG. 13B shows a view 1000a of an embodiment in which at least one of the pillars 902 is removed and at least one of the pillars 902 remains. The skilled artisan will recognize that selective removal of some of the pillars can be effected by any suitable technique including, but not limited to, masking and lithography. While not illustrated further, the embodiment illustrated in FIG. 13B can be used in further processing as described below.

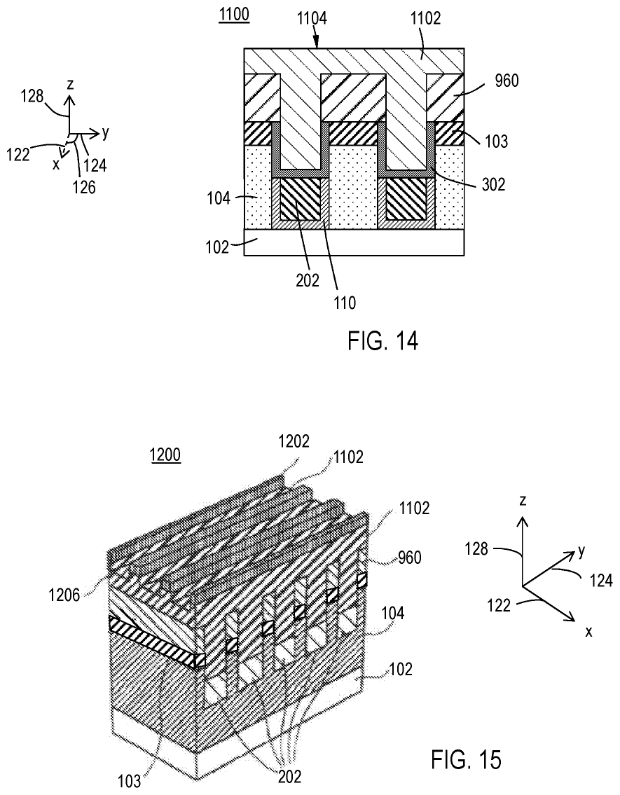

FIG. 14 is a view 1100 and that is similar to FIG. 13 after an insulating layer 1102 is deposited into trenches 1002 to form filled vias according to one embodiment. As shown in FIG. 14, insulating layer 1102 overfills the trenches 1002 so that portions of the insulating layer 1102 are deposited on the top portions of the insulating layer 960. In one embodiment, the thickness of the insulating layer 1102 is sufficient so that the top surface 1104 of the insulating layer 1102 is above or of similar height to the insulating layer 960. In another embodiment, portions (i.e. overburden) of the insulating layer 1102 are removed using one or more of CMP or a back etch technique to even out with the top portions of the insulating layer 960, and then another insulating layer (not shown) is deposited onto the top portions of the insulating layer 960 and insulating layer 1102. As shown in FIG. 14, insulating layer 1102 is deposited on the sidewalls and bottom of the trenches 1002. As shown in FIG. 14, the insulating layer 1102 is deposited on the second conformal liner 302 and portions of the insulating layer 960. In another embodiment, when the second conformal liner 302 is removed, the insulating layer 1102 is directly deposited on the recessed conductive lines 202, portions of the capping layer 103, and portions of the insulating layer 104 and insulating layer 960. In one embodiment, the insulating layer 1102 is etch selective to the insulating layer 960. Generally, etch selectivity between two materials is defined as the ratio between their etching rates at similar etching conditions. In one embodiment, the ratio of the etching rate of the insulating layer 1102 to that of the insulating layer 960 is at least 5:1, 10:1, 15:1, 20:1 or 25:1. In one embodiment, the ratio of the etching rates of the insulating layer 1102 to that of the insulating layer 960 is in an approximate range from about 2:1 to about 50:1, or in the range of about 3:1 to about 30:1, or in the range of about 4:1 to about 20:1.

In one embodiment, insulating layer 1102 is a low-κ gapfill layer. In one embodiment, insulating layer 1102 is a flowable silicon oxide carbide (FSiOC) layer. In some other embodiments, insulating layer 1102 is an oxide layer, e.g., silicon dioxide, or any other electrically insulating layer determined by an electronic device design. In one embodiment, insulating layer 1102 is an interlayer dielectric (ILD). In one embodiment, insulating layer 1102 is a low-κ dielectric that includes, but is not limited to, materials such as, e.g., silicon dioxide, silicon oxide, a carbon based material, e.g., a porous carbon film carbon doped oxide (“CDO”), e.g., carbon doped silicon dioxide, porous silicon dioxide, porous silicon oxide carbide hydride (SiOCH), silicon nitride, or any combination thereof. In one embodiment, insulating layer 1102 is a dielectric material having κ-value less than 3. In more specific embodiment, insulating layer 1102 is a dielectric material having κ-value in an approximate range from about 2.2 to about 2.7. In one embodiment, insulating layer 1102 includes a dielectric material having κ-value less than 2. In one embodiment, insulating layer 1102 represents one of the insulating layers described above with respect to insulating layer 104 and insulating layer 960.

In one embodiment, insulating layer 1102 is a low-κ interlayer dielectric to isolate one metal line from other metal lines. In one embodiment, insulating layer 1102 is deposited using one of deposition techniques, such as but not limited to a CVD, spin-on, an ALD, PVD, MBE, MOCVD, or other low-k insulating layer deposition techniques known to one of ordinary skill in the art of microelectronic device manufacturing.

FIG. 15 is a view 1200 after a hard mask layer 1202 is deposited on insulating layer 1102 according to one embodiment. FIG. 15 is different from FIG. 14 in that the third conformal liner 701 and the second conformal liner 302 are removed, so that insulating layer 1102 is directly deposited on the recessed conductive lines 202, portions of the capping layer 103, and on portions of the insulating layer 104 and insulating layer 960, as described above. In one embodiment, hard mask layer 1202 is a metallization layer hard mask. As shown in FIG. 15, the hard mask layer 1202 is patterned to define a plurality of trenches 1206. As shown in FIG. 15, the trenches 1206 extend along a Y axis (direction) 124 that crosses an X axis (direction) 122 at an angle. In one embodiment, Y axis 124 is substantially perpendicular to Y axis 124. In one embodiment, patterned hard mask layer 1202 is a carbon hard mask layer, a metal oxide hard mask layer, a metal nitride hard mask layer, a silicon nitride hard mask layer, a silicon oxide hard mask layer, a carbide hard mask layer, or other hard mask layer known to one of ordinary skill in the art of microelectronic device manufacturing. In one embodiment, the patterned hard mask layer 1202 is formed using one or more hard mask patterning techniques known to one of ordinary skill in the art of microelectronic device manufacturing. In one embodiment, the insulating layer 1102 is etched through a patterned hard mask layer to form trenches 1206 using one or more of etching techniques known to one of ordinary skill in the art of microelectronic device manufacturing. In one embodiment, the size of trenches in the insulating layer 1102 is determined by the size of conductive lines formed later on in a process.

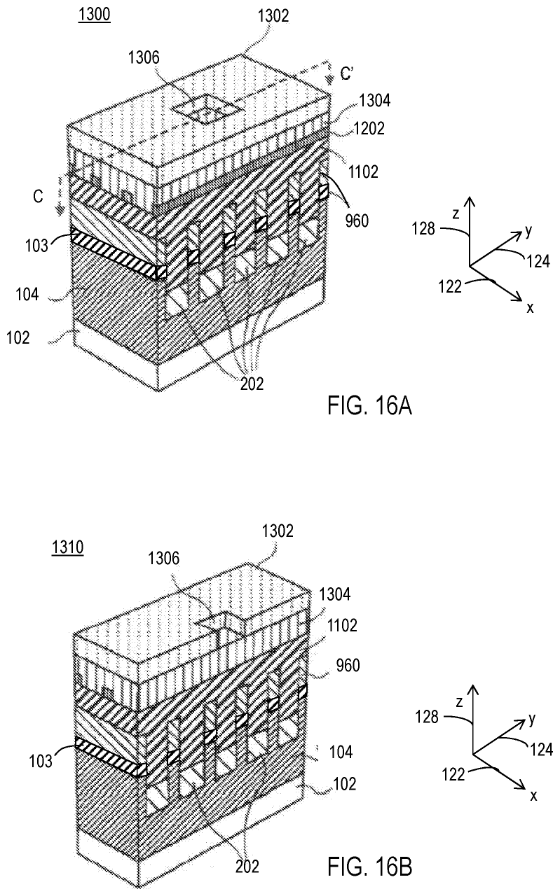

FIG. 16A is a view 1300 similar to FIG. 15, after a mask layer 1302 is deposited on an insulating layer 1304 on a patterned hard mask layer 1202 according to one embodiment. FIG. 16B is a cross-sectional view 1310 of FIG. 13A along an axis C-C′.

As shown in FIGS. 16A and 16B, an opening 1306 is formed in hard mask layer 1202. Opening 1306 is formed above one of the recessed conductive lines 202, as shown in FIGS. 13A and 13B. In one embodiment, the opening 1306 defines a trench portion of the fully self-aligned via formed later on in a process.

In one embodiment, mask layer 1302 includes a photoresist layer. In one embodiment, mask layer 1302 includes one or more hard mask layers. In one embodiment, the insulating layer 1304 is a hard mask layer. In one embodiment, insulating layer 1304 includes a bottom anti-reflective coating (BARC) layer. In one embodiment, insulating layer 1304 includes a titanium nitride (TiN) layer, a tungsten carbide (WC) layer, a tungsten bromide carbide (WBC) layer, a carbon hard mask layer, a metal oxide hard mask layer, a metal nitride hard mask layer, a silicon nitride hard mask layer, a silicon oxide hard mask layer, a carbide hard mask layer, other hard mask layer, or any combination thereof. In one embodiment, insulating layer 1304 represents one of the insulating layers described above. In one embodiment, mask layer 1302 is deposited using one or more mask layer deposition techniques known to one of ordinary skill in the art of microelectronic device manufacturing. In one embodiment, insulating layer 1304 is deposited using one of deposition techniques, such as but not limited to a CVD, PVD, MBE, NOCVD, spin-on, or other insulating layer deposition techniques known to one of ordinary skill in the art of microelectronic device manufacturing. In one embodiment, the opening 1306 is formed using one or more of the patterning and etching techniques known to one of ordinary skill in the art of microelectronic device manufacturing.

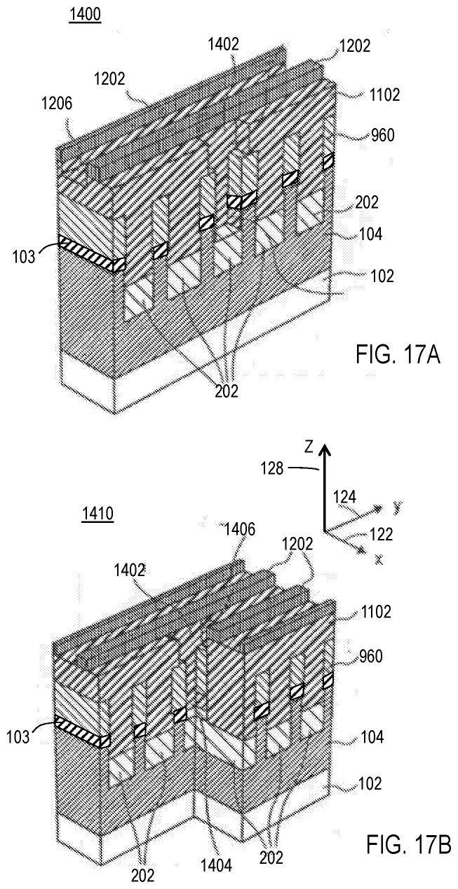

FIG. 17A is a view 1400 similar to FIG. 16B after the insulating layer 1304 and insulating layer 1102 are selectively etched through opening 1306 to form an opening 1402 according to one embodiment. FIG. 17B is a view 1410 similar to FIG. 16A after the insulating layer 1304 and insulating layer 1102 are selectively etched through opening 1306 to form opening 1402 according to one embodiment.

FIG. 17B is different from FIG. 17A in that FIG. 17B shows a cut through opening 1402 along X axis 122 and Y axis 124. As shown in FIGS. 17A and 17B, opening 1402 includes a via portion 1404 and a trench portion 1406. As shown in FIGS. 17A and 17B, via portion 1404 of the opening 1402 is limited along Y axis 124 by insulating layer 802. Via portion 1404 of the opening 1402 is self-aligned along Y axis 124 to one of the recessed conductive lines 202. As shown in FIGS. 17A and 17B, trench portion 1406 is limited along X axis 122 by the features of the hard mask layer 1202 that extend along Y axis 124. In one embodiment, insulating layer 1102 is selectively etched relative to the insulating layer 960 to form opening 1402.

In one embodiment, insulating layer 1102 is selectively etched relative to the insulating layer 960 to form opening 1402. As shown in FIGS. 17A and 174B, mask layer 1302 and insulating layer 1304 are removed. In one embodiment, mask layer 1302 is removed using one or more of the mask layer removal techniques known to one of ordinary skill in the art of microelectronic device manufacturing. In one embodiment, insulating layer 1304 is removed using one or more of the etching techniques known to one of ordinary skill in the art of microelectronic device manufacturing.

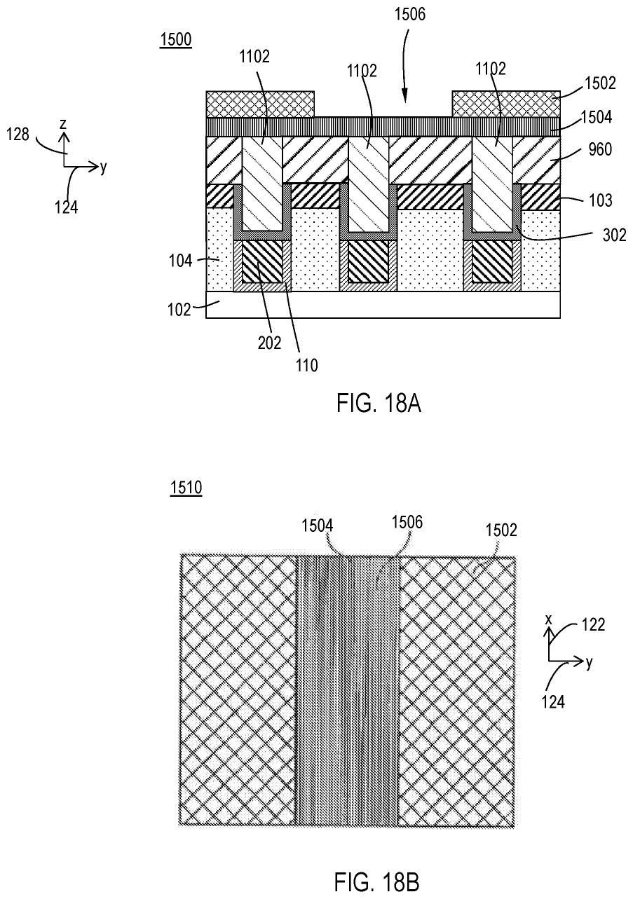

FIG. 18A is a view 1500 similar to FIG. 14, after a mask layer 1502 is deposited on a hard mask layer 1504 on the exposed insulating layer 960 and insulating layer 1102 according to one embodiment. FIG. 18B is a top view 1510 of the electronic device structure depicted in FIG. 18A. As shown in FIG. 18A, a portion of the insulating layer 1102 is removed to even out top portions of the insulating layer 960 with top portions of the insulating layer 1102. As shown in FIGS. 18A and 18B, mask layer 1502 has an opening 1506 to expose hard mask layer 1502.

In one embodiment, the portion of the insulating layer 1102 is removed using a CMP technique known to one of ordinary skill in the art of microelectronic device manufacturing. In one embodiment, a portion of the insulating layer 1102 is etched back to expose the top portion of the insulating layer 960. In another embodiment, a portion of the insulating layer 960 is etched back to a predetermined depth to expose upper portions of the sidewalls and top portions of the insulating layer 1102 in the trenches 1002. In one embodiment, the portion of the insulating layer 960 is etched back using one or more of the dry and wet etching techniques known to one of ordinary skill in the art of microelectronic device manufacturing.

In one embodiment, mask layer 1502 includes a photoresist layer. In one embodiment, mask layer 1502 includes one or more hard mask layers. In one embodiment, mask layer 1502 is a tri-layer mask stack, e.g., Ca 193 nm immersion (193i) or EUV resist mask on a middle layer (ML) (e.g., a silicon containing organic layer or a metal containing dielectric layer) on a bottom anti-reflective coating (BARC) layer on a silicon oxide hard mask. In one embodiment, the hard mask layer 1504 is a metallization layer hard mask to pattern the conductive lines of the next metallization layer. In one embodiment, hard mask layer 1504 includes a titanium nitride (TiN) layer, a tungsten carbide (WC) layer, a tungsten bromide carbide (WBC) layer, a carbon hard mask layer, a metal oxide hard mask layer, a metal nitride hard mask layer, a silicon nitride hard mask layer, a silicon oxide hard mask layer, a carbide hard mask layer, other hard mask layer or any combination thereof. In one embodiment, hard mask layer 1504 represents one of the hard mask layers described above.

In one embodiment, the insulating layer 960 and the insulating layer 1102 are patterned and etched using hard mask layer 1504 to form trenches using one or more patterning and etching techniques known to one or ordinary skill in the art of microelectronic device manufacturing. In one embodiment, the size of trenches in the insulating layer 960 and insulating layer 1102 is determined by the size of conductive lines formed later on in a process.

In one embodiment, the mask layer 1502 is deposited using one or more of the mask deposition techniques known to one of ordinary skill in the art of microelectronic device manufacturing. In one embodiment, hard mask layer 1504 is deposited using one or more hard mask layer deposition techniques, such as but not limited to a CVD, PVD, MBE, MOCVD, spin-on, or other hard mask deposition known to one of ordinary skill in the art of microelectronic device manufacturing. In one embodiment, the opening 1506 is formed using one or more of the patterning and etching techniques known to one of ordinary skill in the art of microelectronic device manufacturing.

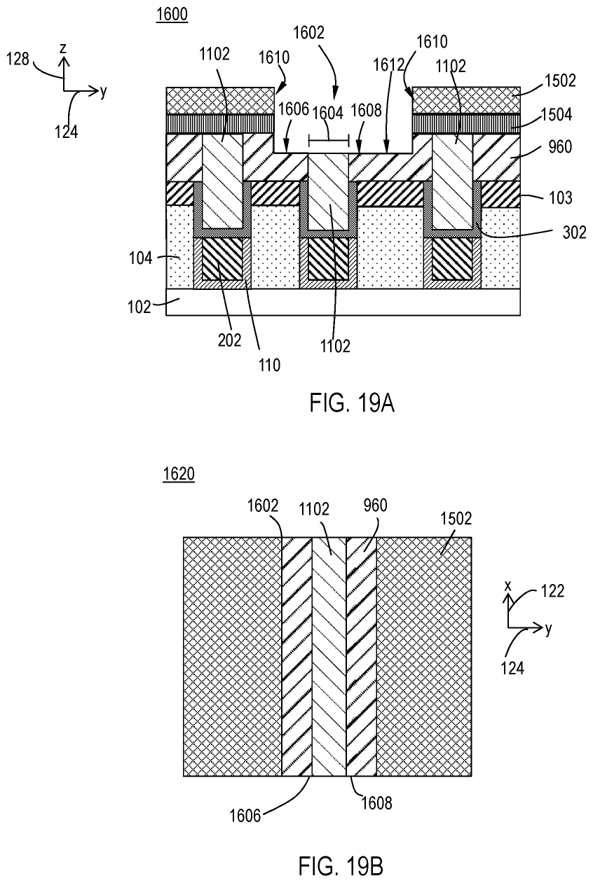

FIG. 19A is a view 1600 similar to FIG. 18A, after portions of the hard mask layer 1504, insulating layer 960 and insulating layer 1102 are removed through opening 1506 to form an opening 1602 in insulating layer 960 according to one embodiment. FIG. 19B is a top view 1620 of the electronic device structure depicted in FIG. 19A. In one embodiment, opening 1602 is a trench opening for a via. As shown in FIGS. 19A and 19B, opening 1602 includes a bottom 1612 that includes a portion 1604 of the insulating layer 1102 between portions 1606 and 1608 of the insulating layer 960. As shown in FIGS. 19A and 19B, opening 1602 includes opposing sidewalls 1610 that include portions of the insulating layer 960. In one embodiment, each sidewall 1610 is substantially orthogonal to bottom 1612. In another embodiment, each sidewall 1610 is slanted relative to bottom 1612 at an angle other than 90 degrees, so that an upper portion of the opening 1602 is greater than a lower portion of the opening 1602.

In one embodiment, opening 1602 having slanted sidewalls is formed using an angled non-selective etch. In one embodiment, hard mask layer 1504 is removed using one or more of wet etching, dry etching, or a combination thereof techniques known to one of ordinary skill in the art of microelectronic device manufacturing. In one embodiment, insulating layer 960 and insulating layer 1102 are removed using a non-selective etch in a trench first dual damascene process. In one embodiment, insulating layer 960 and insulating layer 1102 are etched down to the depth that is determined by time. In another embodiment, insulating layer 960 and insulating layer 1102 are etched non-selectively down to an etch stop layer (not shown). In one embodiment, insulating layer 960 and insulating layer 1102 are non-selectively etched using one or more of wet etching, dry etching, or a combination thereof techniques known to one of ordinary skill in the art of electronic device manufacturing.

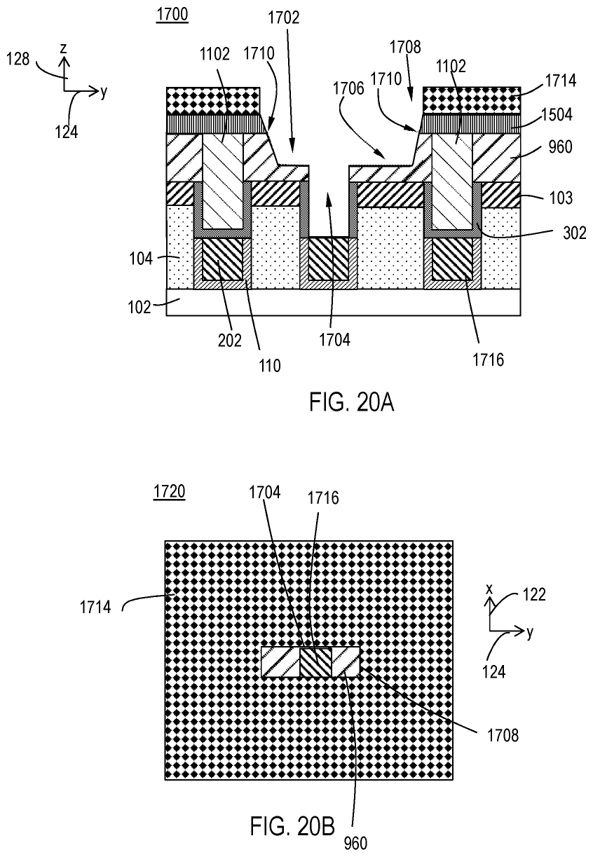

FIG. 20A is a view 1700 similar to FIG. 19A, after a fully self-aligned opening 1702 is formed in insulating layer 960 according to one embodiment. FIG. 20B is a top view 1720 of the electronic device structure depicted in FIG. 20A. As shown in FIGS. 20A and 20B, mask layer 1502 is removed. Mask layer 1502 can be removed using one of the mask layer removal techniques known to one of ordinary skill in the art of microelectronic device manufacturing. A patterned mask layer 1714 is formed on hard mask layer 1504. As shown in FIG. 20B, patterned mask layer 1714 is deposited on the hard mask layer 1504 and into opening 1602. Patterned mask layer 1714 has a mask opening 1708. Patterned mask layer 1714 can be formed using one or more of the mask layer depositing, patterning and etching techniques known to one of ordinary skill in the art of microelectronic device manufacturing.

Fully self-aligned opening 1702 is formed through mask opening 1708. Fully self-aligned opening 1702 includes a trench opening 1706 and a via opening 1704, as shown in FIGS. 20A and 20B. Via opening 1704 is underneath trench opening 1706. In one embodiment, trench opening 1706 is the part that is exposed through mask opening 1708.

In one embodiment, via opening 1704 is formed by selectively etching insulating layer 1102 relative to the insulating layer 960 through mask opening 1708 and trench opening 1706. In one embodiment, trench opening 1706 extends along Y axis 124. As shown in FIG. 20B, trench opening 1706 is greater along Y axis 124 than along X axis 122.

In one embodiment, trench opening 1706 of the opening 1702 is self-aligned along X axis 122 between the features of the hard mask layer 1504 that are used to pattern the upper metallization layer conductive lines that extend along Y axis 124 (not shown). The via opening 1704 of the opening 1702 is self-aligned along Y axis 124 by the insulating layer 802 that is left intact by selectively etching the portion 1604 of the insulating layer 1102 relative to the insulating layer 960. This provides an advantage as the size of the trench opening 1706 does not need to be limited to the size of the cross-section between the conductive line 1716 and one of the conductive lines of the upper metallization layer that provides more flexibility for the lithography equipment. As the portion 1604 is selectively removed relative to the insulating layer 960, the size of the trench opening increases.

As shown in FIGS. 19A and 19B, the portion 1604 is self-aligned with a conductive line 1716 that is one of the lower metallization layer recessed conductive lines 202. That is, the opening 1702 is self-aligned along both X and Y axes.

FIG. 20A is different from FIG. 19A in that FIG. 20A illustrates trench opening 1706 having slanted sidewalls 1710. Each sidewall 1710 is at an angle other than 90 degrees to the top surface of the substrate 102, so that an upper portion of the trench opening 1706 is greater than a lower portion of the trench opening 1706. In another embodiment, the sidewalls 1710 are substantially orthogonal to the top surface of the substrate 102.

In one embodiment, mask layer 1714 includes a photoresist layer. In one embodiment, mask layer 1714 includes one or more hard mask layers. In one embodiment, mask layer 1714 is tri-layer mask stack, e.g., a 193i or EUV resist mask on a ML (e.g., a silicon containing organic layer or a metal containing dielectric layer) on a BARC layer on a silicon oxide hard mask. As shown in FIGS. 20A and 20B, via opening 1704 exposes conductive line 1716. As shown in FIGS. 20A and 20B, conformal liner 302 remains on the sidewalls of via opening 1704, but is removed from the top surface of conductive lines 1716.

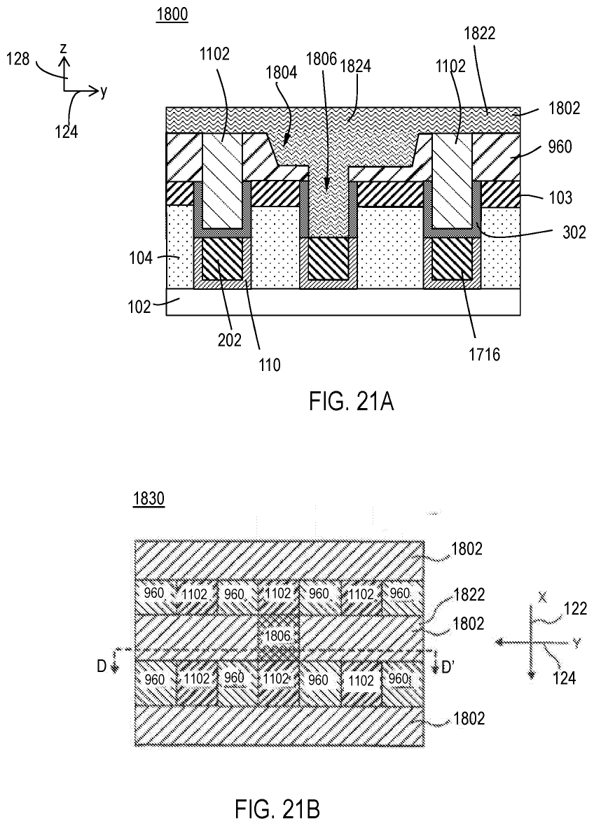

FIG. 21A is a view 1800 similar to FIG. 20A, after an upper metallization layer My comprising conductive lines extending along Y axis 124 is formed according to one embodiment. FIG. 21B is a top view 1830 of the electronic device structure depicted in FIG. 21A. FIG. 21A is a cross-sectional view of FIG. 21B along an axis D-D′. As shown in FIG. 21A, mask layer 1714 and hard mask layer 1504 are removed. In one embodiment, each of the mask layer 1714 and hard mask layer 1504 is removed using one or more of the hard mask layer removal techniques know in one of ordinary skill in the art of microelectronic device manufacturing.

An upper metallization layer My includes a set of conductive lines 1802 that extend on portions of insulating layer 1102 and portions of insulating layer 960. As shown in FIG. 21B, the portions of the insulating layer 1102 are between the portions of the insulating layer 960. Conductive lines 1802 extend along Y axis 124. A fully self-aligned via 1824 includes a trench portion 1804 and a via portion 1806. Via portion 1806 is underneath trench portion 1804. The fully self-aligned via 1824 is between the lower metallization layer comprising recessed conductive lines 202 that extend along X axis 122 and the upper metallization layer comprising conductive lines 1802. As shown in FIGS. 21A and 21B, the via portion 1806 is directly on conductive line 1716 with sidewalls of conformal liner 302. As shown in FIGS. 21A and 21B, the via portion 1806 of the via 1824 is self-aligned along the Y axis 124 to conductive line 1716 that is one of the recessed conductive lines 202. The via portion 1806 of the via 1824 is self-aligned along the X axis (direction) 122 to a conductive line 1822 that is one of the conductive lines 1802. As shown in FIGS. 21A and 21B, the via portion 1806 is a part of the conductive line 1822. As shown in FIGS. 21A and 21B, the size of the via portion 1806 is determined by the size of the cross-section between the conductive line 1716 and conductive line 1822.

In one embodiment, forming the conductive lines 1802 and via 1824 involves filling the trenches in the insulating layer and the opening 1702 with a layer of conductive material. In one embodiment, a base layer (not shown) is first deposited on the internal sidewalls and bottom of the trenches and the opening 1702, and then the conductive layer is deposited on the base layer. In one embodiment, the base layer includes a conductive seed layer (not shown) deposited on a conductive barrier layer (not shown). The seed layer can include copper, and the conductive barrier layer can include aluminum, titanium, tantalum, tantalum nitride, and the like metals. The conductive barrier layer can be used to prevent diffusion of the conductive material from the seed layer, e.g., copper, into the insulating layer. Additionally, the conductive barrier layer can be used to provide adhesion for the seed layer (e.g., copper).

In one embodiment, to form the base layer, the conductive barrier layer is deposited onto the sidewalls and bottom of the trenches, and then the seed layer is deposited on the conductive barrier layer. In another embodiment, the conductive base layer includes the seed layer that is directly deposited onto the sidewalls and bottom of the trenches. Each of the conductive barrier layer and seed layer may be deposited using any thin film deposition technique known to one of ordinary skill in the art of semiconductor manufacturing, e.g., sputtering, blanket deposition, and the like. In one embodiment, each of the conductive barrier layer and the seed layer has the thickness in an approximate range from about 1 nm to about 100 nm. In one embodiment, the barrier layer may be a thin dielectric that has been etched to establish conductivity to the metal layer below. In one embodiment, the barrier layer may be omitted altogether and appropriate doping of the copper line may be used to make a “self-forming barrier”.

In one embodiment, the conductive layer e.g., copper or cobalt, is deposited onto the seed layer of base later of copper, by an electroplating process. In one embodiment, the conductive layer is deposited into the trenches using a damascene process known to one of ordinary skill in the art of microelectronic device manufacturing. In one embodiment, the conductive layer is deposited onto the seed layer in the trenches and in the opening 1702 using a selective deposition technique, such as but not limited to electroplating, electrolysis, a CVD, PVD, MBE, MOCVD, ALD, spin-on, or other deposition techniques known to one of ordinary skill in the art of microelectronic device manufacturing.

In one embodiment, the choice of a material for conductive layer for the conductive lines 1802 and via 1824 determines the choice of a material for the seed layer. For example, if the material for the conductive lines 1802 and via 1824 includes copper, the material for the seed layer also includes copper. In one embodiment, the conductive lines 1802 and via 1824 include a metal, for example, copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), vanadium (V), molybdenum (Mo), palladium (Pd), gold (Au), silver (Ag), platinum (Pt), indium (In), tin (Sn), lead (Pb), antimony (Sb), bismuth (Bi), zinc (Zn), cadmium (Cd), or any combination thereof.

In alternative embodiments, examples of the conductive materials that may be used for the conductive lines 1802 and via 1824 include metals, e.g., copper, tantalum, tungsten, ruthenium, titanium, hafnium, zirconium, aluminum, silver, tin, lead, metal alloys, metal carbides, e.g., hafnium carbide, zirconium carbide, titanium carbide, tantalum carbide, aluminum carbide, other conductive materials, or any combination thereof.

In one embodiment, portions of the conductive layer and the base layer are removed to even out top portions of the conductive lines 1802 with top portions of the insulating layer 960 and insulating layer 1102 using a chemical-mechanical polishing (“CMP”) technique known to one of ordinary skill in the art of microelectronic device manufacturing.

In one non-limiting example, the thickness of the conductive lines 1802 is in an approximate range from about 15 nm to about 1000 nm. In one non-limiting example, the thickness of the conductive lines 1802 is from about 20 nm to about 200 nm. In one non-limiting example, the width of the conductive lines 1802 is in an approximate range from about 5 nm to about 500 nm. In one non-limiting example, the spacing (pitch) between the conductive lines 1802 is from about 2 nm to about 500 nm. In more specific non-limiting example, the spacing (pitch) between the conductive lines 1802 is from about 5 nm to about 50 nm.

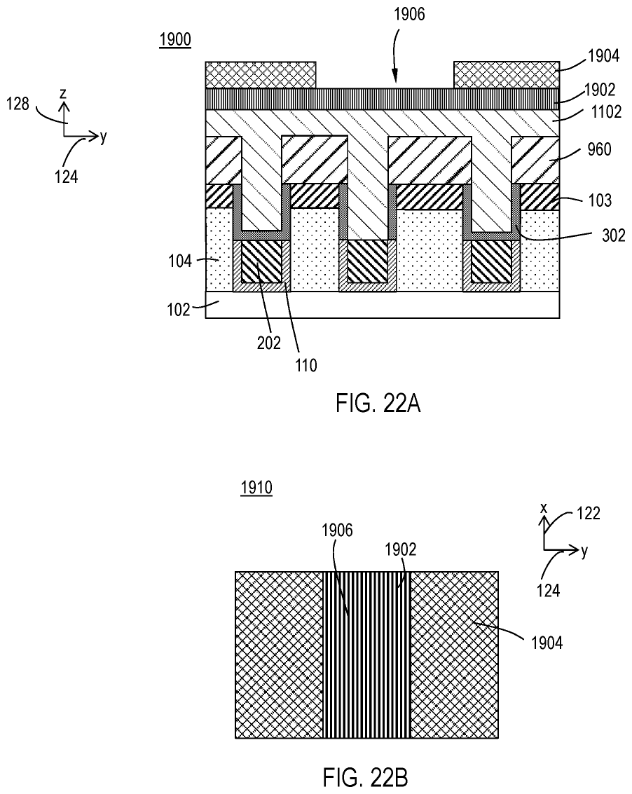

FIGS. 22 through 26 (including both A and B designations) illustrate another embodiment of the disclosure. FIG. 22A is a view 1900 similar to FIG. 14, after a mask layer 1904 is deposited on a hard mask layer 1902 on the insulating layer 1102 according to one embodiment. FIG. 22B is a top view 1910 of the electronic device structure depicted in FIG. 22A. As shown in FIGS. 22A and 22B, mask layer 1904 has an opening 1906 to expose hard mask layer 1902.

In one embodiment, mask layer 1904 includes a photoresist layer. In one embodiment, mask layer 1904 includes one or more hard mask layers. In one embodiment, mask layer 1904 is a tri-layer mask stack, e.g., a 193 nm immersion (193i) or EUV resist mask on a middle layer (ML) (e.g., a silicon containing organic layer or a metal containing dielectric layer) on a bottom anti-reflective coating (BARC) layer on a silicon oxide hard mask. In one embodiment, the hard mask layer 1902 is a metallization layer hard mask to pattern the conductive lines of the next metallization layer. In one embodiment, hard mask layer 1902 includes a titanium nitride (TiN) layer, a tungsten carbide (WC) layer, a tungsten bromide carbide (WBC) layer, a carbon hard mask layer, a metal oxide hard mask layer, a metal nitride hard mask layer, a silicon nitride hard mask layer, a silicon oxide hard mask layer, a carbide hard mask layer, other hard mask layer or any combination thereof. In one embodiment, hard mask layer 1902 represents one of the hard mask layers described above.

In one embodiment, the mask layer 1904 is deposited using one or more of the mask deposition techniques known to one of ordinary skill in the art of microelectronic device manufacturing. In one embodiment, hard mask layer 1902 is deposited using one or more hard mask layer deposition techniques, such as but not limited to a CVD, PVD, MBE, MOCVD, spin-on, or other hard mask deposition known to one of ordinary skill in the art of microelectronic device manufacturing. In one embodiment, the opening 1906 is formed using one or more of the patterning and etching techniques known to one of ordinary skill in the art of microelectronic device manufacturing.

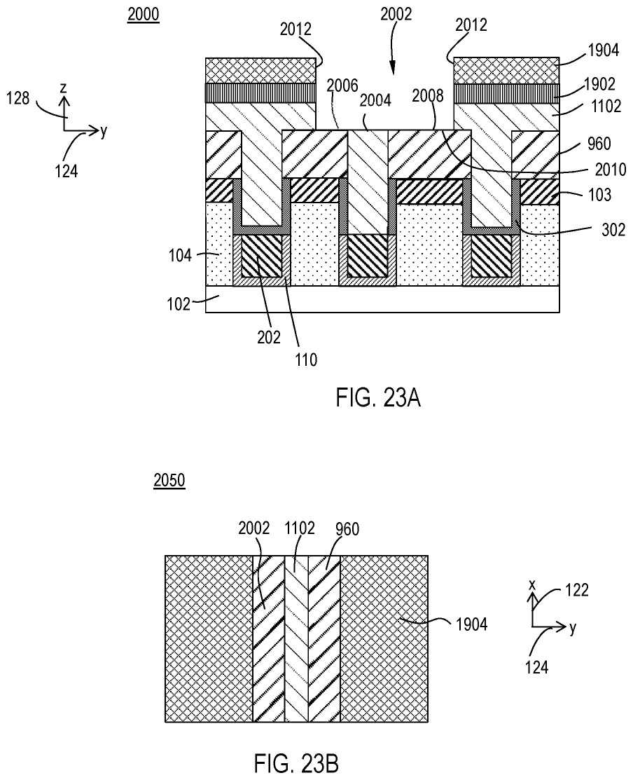

FIG. 23A is a view 2000 similar to FIG. 22A, after portions of the hard mask layer 1902 and insulating layer 1102 are removed through opening 1906 to form an opening 2002 in insulating layer 1102 according to one embodiment. FIG. 23B is a top view 2050 of the electronic device structure depicted in FIG. 23A. In one embodiment, opening 2002 is a trench opening for a via. As shown in FIGS. 23A and 23B, opening 2002 includes a bottom 2010 that includes a portion 2004 of the insulating layer 1102 between portions 2006 and 2008 of the insulating layer 960. As shown in FIGS. 23A and 23B, opening 2002 includes opposing sidewalls 2012 that include portions of the insulating layer 1102. In one embodiment, each sidewall 2012 is substantially orthogonal to bottom 2010. In another embodiment, each sidewall 2012 is slanted relative to bottom 2010 at an angle other than 90 degrees, so that an upper portion of the opening 2002 is greater than a lower portion of the opening 2002.

In one embodiment, opening 2002 having slanted sidewalls is formed using an angled non-selective etch. In one embodiment, hard mask layer 1902 is removed using one or more of wet etching, dry etching, or a combination thereof techniques known to one of ordinary skill in the art of microelectronic device manufacturing. In one embodiment, insulating layer 1102 is removed using a non-selective etch in a trench first dual damascene process. In one embodiment, insulating layer 1102 is etched down to the depth that is determined by time. In another embodiment, insulating layer 1102 is etched non-selectively down to an etch stop layer (not shown). In one embodiment, insulating layer 1102 is non-selectively etched using one or more of wet etching, dry etching, or a combination thereof techniques known to one of ordinary skill in the art of electronic device manufacturing.

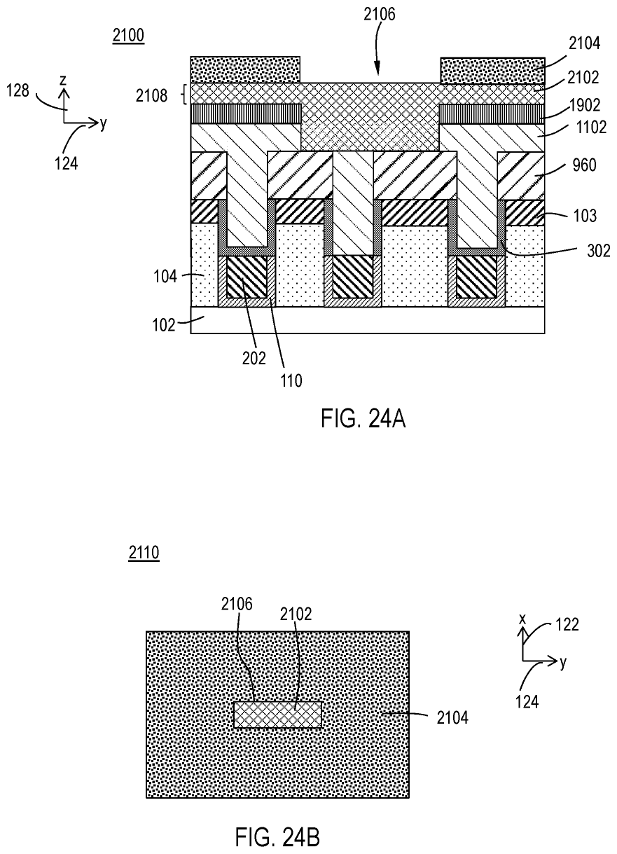

FIG. 24A is a view 2100 similar to FIG. 23A, after mask layer 1904 is removed, planarization filling layer 2102 is formed and mask layer 2104 with opening 2106, which is a fully self-aligned opening, is formed according to one embodiment. FIG. 24B is a top view 2110 of the electronic device structure depicted in FIG. 24A. As shown in FIGS. 24A and 24B, mask layer 1904 is removed. Mask layer 1904 can be removed using one of the mask layer removal techniques known to one of ordinary skill in the art of microelectronic device manufacturing. A planarization filling layer 2102 is formed in opening 2002 onto the tops of exposed insulating layer 960 and insulating layer 1102. The planarization filling layer 2102 illustrated is formed so that an overburden 2108 is formed on hard mask layer 1902. In some embodiments, the planarization filling layer 2102 is formed to be substantially coplanar with the hard mask layer 1902. In some embodiments, the planarization filling layer 2102 is planarized, for example, by a CMP process. The planarization filling layer 2102 can be any suitable material including, but not limited to, BARC (Bottom Anti-Reflective Coating) layer (e.g., spin-on polymers containing C and H, or Si), DARC (Dielectric Anti-Reflective Coating) layer or an OPL (Organic Planarization Layer). The planarization filling layer 2102 of some embodiments is deposited by CVD or ALD. In some embodiments, the planarization filling layer 2102 comprises one or more atoms of Si, O, N, C or H.

A patterned mask layer 2104 is formed on hard mask layer 1902. As shown in FIG. 24B, patterned mask layer 2104 is deposited on the planarization filling layer 2102. Patterned mask layer 2104 has an opening 2106. Patterned mask layer 2104 can be formed using one or more of the mask layer depositing, patterning and etching techniques known to one of ordinary skill in the art of microelectronic device manufacturing.

In one embodiment, mask layer 2104 includes a photoresist layer. In one embodiment, mask layer 2104 includes one or more hard mask layers. In one embodiment, mask layer 2104 is tri-layer mask stack, e.g., a 193i or EUV resist mask on a ML (e.g., a silicon containing organic layer or a metal containing dielectric layer) on a BARC layer on a silicon oxide hard mask.

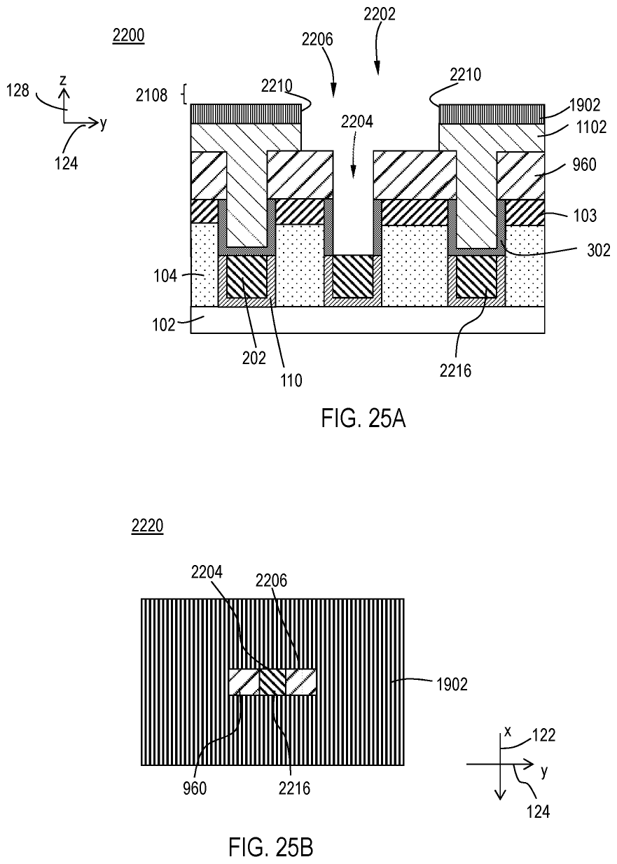

FIG. 25A is a view 2200 similar to FIG. 24A, after removing the planarization filling layer 2102 and insulating layer 1102 through opening 2106. FIG. 25B is a top view 2220 of the electronic device structure depicted in FIG. 25A. As shown in FIGS. 25A and 25B, the embodiment illustrated has the patterned mask layer 2104 and planarization filling layer 2102 removed from hard mask layer 1902. A fully self-aligned opening 2202 is formed through opening 2106. Fully self-aligned opening 2202 includes a trench opening 2206 and a via opening 2204, as shown in FIGS. 24A and 24B. Via opening 2204 is underneath trench opening 2206.

In one or more embodiments, via opening 2204 is formed by selectively etching insulating layer 1102 relative to the insulating layer 960 through opening 2106 and trench opening 2206. In one embodiment, trench opening 2206 extends along Y axis 124. As shown in FIG. 25B, trench opening 2206 is greater along Y axis 124 than along X axis 122.

In one embodiment, trench opening 2206 of the opening 2202 is self-aligned along X-axis between the features of the hard mask layer 1902 that are used to pattern the upper metallization layer conductive lines that extend along Y axis 124 (not shown). The via opening 2204 of the opening 2202 is self-aligned along Y axis 124 by the insulating layer 960 that is left intact by selectively etching the portion 2004 of the insulating layer 1102 relative to the insulating layer 960. This provides an advantage as the size of the trench opening 2206 does not need to be limited to the size of the cross-section between the conductive line 2216 and one of the conductive lines of the upper metallization layer that provides more flexibility for the lithography equipment. As the portion 2004 is selectively removed relative to the insulating layer 960, the size of the trench opening increases.

As shown in FIGS. 25A and 25B, the portion 2004 is self-aligned with a conductive line 2216 that is one of the lower metallization layer recessed conductive lines 202. That is, the opening 2202 is self-aligned along both X and Y axes.

FIG. 25A illustrates trench opening 2206 having sidewalls 2210 that are substantially orthogonal to the top surface of the substrate 102. In some embodiments, each sidewall 2210 is at an angle other than 90 degrees to the top surface of the substrate 102, so that an upper portion of the trench opening 2206 is greater than a lower portion of the trench opening 2206.

As shown in FIGS. 25A and 25B, via opening 2204 exposes conductive line 2216 and conformal liner 302 on the sidewalls of via opening 2204.

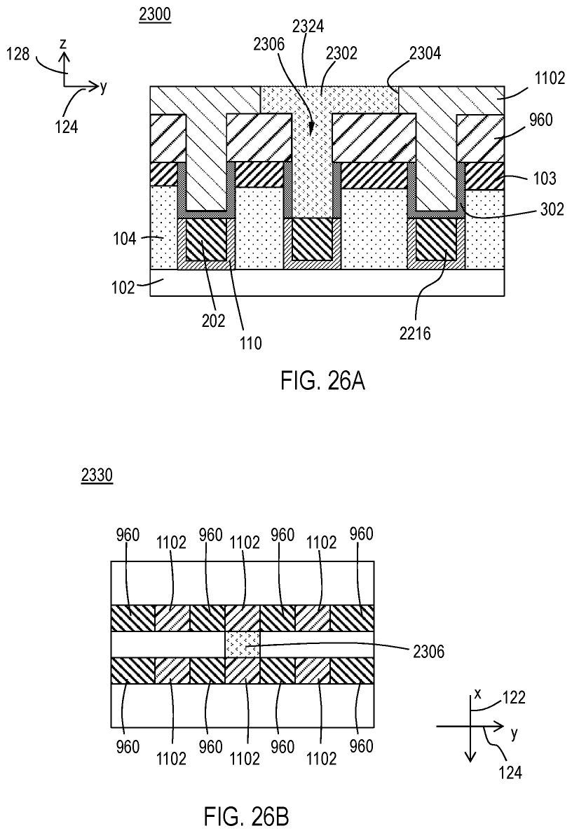

FIG. 26A is a view 2300 similar to FIG. 25A, after an upper metallization layer My comprising conductive lines extending along Y axis 124 is formed according to one embodiment. FIG. 26B is a top view 2330 of the electronic device structure depicted in FIG. 26A. FIG. 26A is a cross-sectional view of FIG. 26B taken along an axis D-D′. As shown in FIG. 26A, hard mask layer 1902 is removed. In one embodiment, hard mask layer 1902 is removed using one or more of the hard mask layer removal techniques know in one of ordinary skill in the art of microelectronic device manufacturing.

An upper metallization layer My includes a set of conductive lines 2302 that extend on portions of insulating layer 960. In the embodiment illustrated in FIG. 26A, the conductive lines 2302 are filled to be co-planar with the top of insulating layer 1102. In some embodiments, the conductive lines 2302 extend above the top surface of insulating layer 1102, similar to that shown in FIG. 21A.

As shown in FIG. 26B, the portions of the insulating layer 1102 are between the portions of the insulating layer 960. Conductive lines 2302 extend along Y axis 124. A fully self-aligned via 2324 includes a trench portion 2304 and a via portion 2306. Via portion 2306 is underneath trench portion 2304. The fully self-aligned via 2324 is between the lower metallization layer comprising recessed conductive lines 202 that extend along X axis 122 and the upper metallization layer comprising conductive lines 2302. As shown in FIGS. 26A and 26B, the via portion 2306 of the via 2324 is self-aligned along the Y axis 124 to conductive line 2216 that is one of the recessed conductive lines 202. The via portion 2306 of the via 2324 is self-aligned along the X axis 122. In one embodiment, the via portion 2306 is directly on conductive line 2216 and the sidewalls of the via portion 2306 are the conformal liner 302.

In one embodiment, forming the conductive lines 2302 and via 2324 involves filling the trenches in the insulating layer and the opening 2202 with a layer of conductive material. In one embodiment, a base layer (not shown) is first deposited on the internal sidewalls and bottom of the trenches and the opening 2202, and then the conductive layer is deposited on the base layer. In one embodiment, the base layer includes a conductive seed layer (not shown) deposited on a conductive barrier layer (not shown). The seed layer can include copper, and the conductive barrier layer can include aluminum, titanium, tantalum, tantalum nitride, and the like metals. The conductive barrier layer can be used to prevent diffusion of the conductive material from the seed layer, e.g., copper, into the insulating layer. Additionally, the conductive barrier layer can be used to provide adhesion for the seed layer (e.g., copper or cobalt).

In one embodiment, to form the base layer, the conductive barrier layer is deposited onto the sidewalls and bottom of the trenches, and then the seed layer is deposited on the conductive barrier layer. In another embodiment, the conductive base layer includes the seed layer that is directly deposited onto the sidewalls and bottom of the trenches. Each of the conductive barrier layer and seed layer may be deposited using any thin film deposition technique known to one of ordinary skill in the art of semiconductor manufacturing, e.g., sputtering, blanket deposition, and the like. In one embodiment, each of the conductive barrier layer and the seed layer has the thickness in an approximate range from about 1 nm to about 100 nm. In one embodiment, the barrier layer may be a thin dielectric that has been etched to establish conductivity to the metal layer below. In one embodiment, the barrier layer may be omitted altogether and appropriate doping of the copper line may be used to make a “self-forming barrier”.

In one embodiment, the conductive layer e.g., copper, is deposited onto the seed layer of base later of copper, by an electroplating process. In one embodiment, the conductive layer is deposited into the trenches using a damascene process known to one of ordinary skill in the art of microelectronic device manufacturing. In one embodiment, the conductive layer is deposited onto the seed layer in the trenches and in the opening 2202 using a selective deposition technique, such as but not limited to electroplating, electrolysis, a CVD, PVD, MBE, MOCVD, ALD, spin-on, or other deposition techniques known to one of ordinary skill in the art of microelectronic device manufacturing.

In one embodiment, the choice of a material for conductive layer for the conductive lines 2302 and via 2324 determines the choice of a material for the seed layer. For example, if the material for the conductive lines 2302 and via 2324 includes copper, the material for the seed layer also includes copper. In one embodiment, the conductive lines 2302 and via 2324 include a metal, for example, copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), vanadium (V), molybdenum (Mo), palladium (Pd), gold (Au), silver (Ag), platinum (Pt), indium (In), tin (Sn), lead (Pb), antimony (Sb), bismuth (Bi), zinc (Zn), cadmium (Cd), or any combination thereof.

In alternative embodiments, examples of the conductive materials that may be used for the conductive lines 2302 and via 2324 are, but not limited to, metals, e.g., copper, tantalum, tungsten, ruthenium, titanium, hafnium, zirconium, aluminum, silver, tin, lead, metal alloys, metal carbides, e.g., hafnium carbide, zirconium carbide, titanium carbide, tantalum carbide, aluminum carbide, other conductive materials, or any combination thereof.

In one embodiment, portions of the conductive layer and the base layer are removed to even out top portions of the conductive lines 2302 with top portions of the insulating layer 1102 using a chemical-mechanical polishing (“CMP”) technique known to one of ordinary skill in the art of microelectronic device manufacturing.

In one non-limiting example, the thickness of the conductive lines 2302 is in an approximate range from about 15 nm to about 1000 nm. In one non-limiting example, the thickness of the conductive lines 2302 is from about 20 nm to about 200 nm. In one non-limiting example, the width of the conductive lines 2302 is in an approximate range from about 5 nm to about 500 nm. In one non-limiting example, the spacing (pitch) between the conductive lines 2302 is from about 2 nm to about 500 nm. In more specific non-limiting example, the spacing (pitch) between the conductive lines 2302 is from about 5 nm to about 50 nm.

In an embodiment, the upper metallization layer My is configured to connect to other metallization layers (not shown). In an embodiment, the metallization layer My is configures to provide electrical contact to electronic devices, e.g., transistors, memories, capacitors, resistors, optoelectronic devices, switches, and any other active and passive electronic devices that are separated by an electrically insulating layer, for example, an interlayer dielectric, a trench insulation layer, or any other insulating layer known to one or ordinary skill in the art of electronic device manufacturing.

In the foregoing specification, embodiments of the disclosure have been described with reference to specific exemplary embodiments thereof. It will be evident that various modifications may be made thereto without departing from the broader spirit and scope of the embodiments of the disclosure as set forth in the following claims. The specification and drawings are, accordingly, to be regarded in an illustrative sense rather than a restrictive sense.

What is claimed is:

1. A method to provide a self-aligned via, the method comprising:
providing a substrate having a first insulating layer thereon, the first insulating layer having a top surface and a plurality of trenches formed along a first direction, the plurality of trenches having recessed first conductive lines extending along the first direction and having a first conductive surface below the top surface of the first insulating layer;
forming a sacrificial layer in the plurality of trenches on the recessed first conductive lines to form an sacrificial layer overburden on the top surface of the first insulating layer;
planarizing the substrate to remove the sacrificial layer overburden and a portion of the first insulating layer to expose the top surface of the first insulating layer and form a plurality of filled trenches having sharp top corners;
removing the sacrificial layer to expose the recessed first conductive lines;
depositing a first metal film on the recessed first conductive lines; and
forming pillars from the first metal film on the recessed first conductive lines, the pillars extending orthogonal to the top surface of the first insulating layer.

2. The method of claim 1, further comprising:
depositing a second insulating layer around the pillars and on the top surface of the first insulating layer; and
selectively removing at least one of the pillars to form at least one opening in the second insulating layer, leaving at least one pillar.

3. The method of claim 2, further comprising depositing a second conductive material in the at least one opening to form a via.

4. The method of claim 2, further comprising:
depositing a third insulating layer in the at least one opening onto the recessed first conductive lines to form filled vias;
etching a portion of the third insulating layer relative to the second insulating layer to form a via opening to at least one of the recessed first conductive lines; and
forming second conductive lines on portions of the second insulating layer and the third insulating layer, the second conductive lines extending along a second direction that crosses the first direction at an angle.

5. The method of claim 4, wherein the recessed first conductive lines and second conductive lines independently comprise one or more of copper, ruthenium, nickel, cobalt, chromium, iron, manganese, titanium, aluminum, hafnium, tantalum, tungsten, vanadium, molybdenum, palladium, gold, silver, platinum, indium, tin, lead, antimony, bismuth, zinc, or cadmium.

6. The method of claim 4, wherein the recessed first conductive lines and the second conductive lines independently comprise one or more of copper or cobalt.

7. The method of claim 1, wherein the sacrificial layer comprises an oxide formed by flowable CVD.

8. The method of claim 1, wherein the first metal film comprises tungsten and wherein the pillars are formed by oxidizing the first metal film to form tungsten oxide.

9. The method of claim 1, wherein the recessed first conductive lines have a width in a range of about 2 nm to about 15 nm.

10. The method of claim 4, wherein the first insulating layer, the second insulating layer, and the third insulating layer are independently selected from: oxides, carbon doped oxides, porous silicon dioxide, carbides, oxycarbides, nitrides, oxynitrides, oxycarbonitrides, polymers, phosphosilicate glass, fluorosilicate (SiOF) glass, organosilicate glass (SiOCH), or any combinations thereof.

11. The method of claim 2, wherein the first insulating layer and the second insulating layer are comprised of the same material.

12. The method of claim 1, wherein the recessed first conductive lines are recessed in a range of about 10 nm to about 50 nm.

13. The method of claim 1, wherein the pillars are removed by etching with a solution of HF and HNO₃, a solution of NH₄OH and H₂O₂, WCl₅, WF₆, niobium fluoride, chlorine with a hydrocarbon.

14. The method of claim 1, wherein the substrate further comprises a capping layer on the first insulating layer.

15. An electronic device comprising:
a first metallization layer comprising a set of first conductive lines extending along a first direction, each of the first conductive lines separated from an adjacent first conductive line by a first insulating layer;
a second insulating layer on the first insulating layer;
a second metallization layer on portions of the second insulating layer and a third insulating layer, the second metallization layer comprising a set of second conductive lines extending along a second direction that crosses the first direction at an angle; and
at least one via between the first metallization layer and the second metallization layer, wherein the at least one via is self-aligned along the second direction to one of the first conductive lines, and wherein the at least one via is substantially vertical.

16. The electronic device of claim 15, wherein the at least one via is self-aligned along the first direction to one of the second conductive lines.

17. The electronic device of claim 15, wherein the third insulating layer is etch selective relative to the second insulating layer.

18. The electronic device of claim 15, wherein the first metallization layer and the second metallization layer independently comprise one or more of copper, ruthenium, nickel, cobalt, chromium, iron, manganese, titanium, aluminum, hafnium, tantalum, tungsten, vanadium, molybdenum, palladium, gold, silver, platinum, indium, tin, lead, antimony, bismuth, zinc, or cadmium.

19. The electronic device of claim 15, wherein the first insulating layer, the second insulating layer, and the third insulating layer, are independently selected from: oxides, carbon doped oxides, porous silicon dioxide, carbides, oxycarbides, nitrides, oxynitrides, oxycarbonitrides, polymers, phosphosilicate glass, fluorosilicate (SiOF) glass, organosilicate glass (SiOCH), or any combinations thereof.

20. The electronic device of claim 15, wherein the first conductive lines are recessed in a range of about 10 nm to about 50 nm.

21. The electronic device of claim 15, further comprising a liner between the first conductive lines and the second insulating layer and the first conductive lines and the second metallization layer in the at least one via.

22. The electronic device of claim 15, further comprising a capping layer on the first insulating layer.

23. The electronic device of claim 15, wherein the at least one via has a trench portion that is a part of the one of the second conductive lines and a via portion underneath the trench portion.

24. A method to provide a self-aligned via, the method comprising:
providing a substrate having a first insulating layer thereon and a capping layer on the first insulating layer, the first insulating layer having a top surface and a plurality of trenches formed along a first direction, the plurality of trenches having recessed first conductive lines extending along the first direction and having a first conductive surface below the top surface of the first insulating layer, the first insulating layer comprising ULK;
forming a sacrificial layer in the plurality of trenches on the recessed first conductive lines to form an sacrificial layer overburden on the top surface of the first insulating layer, the sacrificial layer comprising an oxide formed by flowable CVD;
removing the sacrificial layer to expose the recessed first conductive lines;
depositing a first metal film on the recessed first conductive lines, the first metal film comprising tungsten; and
forming pillars from the first metal film on the recessed first conductive lines, the pillars extending orthogonal to the top surface of the first insulating layer.
